(19) United States
(12) Patent Application Publication
(10) Pub. No.: US 2023/0238373 A1
(43) Pub. Date: Jul. 27, 2023

(54) DISPLAY DEVICE AND TILED DISPLAY DEVICE

(71) Applicant: Samsung Display Co., LTD., Yongin-si (KR)

(72) Inventors: Nak Cho CHOI, Yongin-si (KR); Byeong Kyun CHOI, Yongin-si (KR); Jae Phil LEE, Yongin-si (KR); Sun PARK, Yongin-si (KR); Min Chul SHIN, Yongin-si (KR); Sang Woo AN, Yongin-si (KR)

(21) Appl. No.: 18/080,413

(22) Filed: Dec. 13, 2022

(30) Foreign Application Priority Data
Jan. 26, 2022 (KR) 10-2022-0011239
May 11, 2022 (KR) 10-2022-0057573

(51) Int. Cl. H01L 25/16; H01L 27/12; H01L 23/00

(52) U.S. Cl. CPC H01L 25/167; H01L 27/1248; H01L 24/05; H01L 24/29; H01L 24/32; H01L 2224/02185; H01L 2224/05026; H01L 2224/05073; H01L 2224/05573; H01L 2224/05561; H01L 2224/05686; H01L 2224/26145; H01L 2224/29016; H01L 2224/29021; H01L 2224/32145; H01L 2924/0549; H01L 2924/12041

(57) ABSTRACT

A display device includes a substrate, a plurality of electrode pads including a first electrode pad and a common electrode pad on the substrate, a light emitting element including a first contact electrode on the first electrode pad and a second contact electrode on the common electrode pad, a conductive adhesive member including a plurality of conductive balls connecting the first electrode pad and the first contact electrode and connecting the common electrode pad and the second contact electrode, and a plurality of protrusions on the substrate and protruding in a thickness direction of the substrate. First protrusions from among the plurality of protrusions overlap the electrode pads in the thickness direction of the substrate.

### CROSS-REFERENCE TO RELATED APPLICATIONS

This application claims priority to and the benefit of Korean Patent Application No. 10-2022-0011239 filed on Jan. 26, 2022, and Korean Patent Application No. 10-2022-0057573 filed on May 11, 2022, in the Korean Intellectual Property Office (KIPO), the entire contents of both of which are incorporated by reference herein.

### BACKGROUND

### 1. Field

The present disclosure relates to a display device and a tiled display device.

### 2. Description of the Related Art

With the advance of information-oriented society, more and more demands are placed on display devices for displaying images in various ways. The display device may be a flat panel display device such as a liquid crystal display, a field emission display and a light emitting display. A light emitting display device may include an organic light emitting display device including an organic light emitting diode (OLED) as a light emitting element or a light emitting diode display device including an inorganic light emitting diode such as a light emitting diode (LED) as a light emitting element.

The display device includes a display area operating in units of pixels displaying an image, and a non-display area (or bezel area) disposed around the display area and in which lines for driving the pixels are disposed. Recently, a bezel-less display device has been released in order to increase or maximize the area of the display area. Accordingly, there is an increasing demand for a display device in which the area of the non-display area is reduced or the non-display area is omitted by forming a line on a side surface of a substrate.

### SUMMARY

Aspects and features of embodiments of the present disclosure provide a display device capable of suppressing occurrence of dark spot defects by suppressing the flow of a conductive ball in a conductive adhesive member connecting a light emitting element and an electrode pad.

However, embodiments of the present disclosure are not limited to those set forth herein. The above and other embodiments of the present disclosure will become more apparent to one of ordinary skill in the art to which the present disclosure pertains by referencing the detailed description of the present disclosure given below.

According to one or more embodiments of the present disclosure, there is provided a display device including a substrate, a plurality of electrode pads including a first electrode pad and a common electrode pad on the substrate, a light emitting element including a first contact electrode on the first electrode pad and a second contact electrode on the common electrode pad, a conductive adhesive member including a plurality of conductive balls connecting the first electrode pad and the first contact electrode and connecting the common electrode pad and the second contact electrode, and a plurality of protrusions on the substrate and protruding in a thickness direction of the substrate. First protrusions from among the plurality of protrusions overlap the plurality of electrode pads in the thickness direction of the substrate.

Second protrusions from among the plurality of protrusions may be located between the first electrode pad and the common electrode pad.

At least some of the plurality of conductive balls may be located between the plurality of protrusions.

The first protrusions may protrude from top surfaces of the plurality of electrode pads.

The display device may further include a planarization layer between the plurality of electrode pads and the substrate, and a pixel defining layer on the planarization layer and surrounding the plurality of electrode pads. The second protrusions may be on a same plane as the pixel defining layer and the plurality of electrode pads.

The first protrusions and the second protrusions may include a same material as the pixel defining layer.

The display device may further include a first passivation layer on the pixel defining layer. The first protrusions may not be covered by the first passivation layer, and the second protrusions may be covered by the first passivation layer.

The first protrusions may be under the plurality of electrode pads.

The display device may further include a planarization layer between the plurality of electrode pads and the substrate. The first protrusions may protrude from one surface of the planarization layer.

The display device may further include a planarization layer between the plurality of electrode pads and the substrate, a pixel defining layer on the planarization layer and surrounding the plurality of electrode pads, and a first passivation layer on some of the plurality of electrode pads and the pixel defining layer. The plurality of protrusions may include a same material as the first passivation layer.

The plurality of protrusions may further include a second protrusion between the first electrode pad and the common electrode pad in a plan view. The first protrusions may be on one surface of the electrode pad, and the second protrusions may protrude from one surface of the first passivation layer.

A maximum length of a protrusion from among the plurality of protrusions may be smaller than a diameter of the conductive ball from among the plurality of conductive balls.

The maximum length of the protrusion may be about 0.5 μm to 1.5 μm, and the diameter of the conductive ball may be about 3 μm to 5 μm.

The plurality of protrusions may have a shape such as a hemisphere, a triangular pyramid, a quadrangular pyramid, and a donut.

A thickness of the first contact electrode may be smaller than a thickness of the second contact electrode.

The first electrode pad and the common electrode pad may be adjacent to each other in a first direction and may extend in a second direction crossing the first direction. The light emitting element may be a flip chip type micro light emitting diode located between the first electrode pad and the common electrode pad.

According to one or more embodiments of the present disclosure, there is provided a display device including a substrate, a plurality of electrode pads including a first electrode pad and a common electrode pad on the substrate, a light emitting element including a first contact electrode on the first electrode pad and a second contact electrode on the common electrode pad, and a conductive adhesive member including a plurality of conductive balls connecting the first electrode pad and the first contact electrode and connecting the common electrode pad and the second contact electrode. The first electrode pad has a first recess recessed from a top surface of the first electrode pad, and the common electrode pad has a second recess recessed from a top surface of the common electrode pad.

The plurality of conductive balls may be in the first recess and the second recess. A diameter of each of the plurality of conductive balls may be greater than a recessed thickness of each of the first recess and the second recess.

The recessed thickness of the first recess may be at least ⅓ of a thickness of the first electrode pad.

The first electrode pad may have a first protrusion protruding from a top surface of the first recess. The common electrode pad may have a second protrusion protruding from a top surface of the second recess.

In the first electrode pad, the first recess and the first protrusion may be arranged to be spaced along one direction. In the common electrode pad, the second recess and the second protrusion may be arranged to be spaced along the one direction.

The light emitting element may overlap the first recess and the second recess in a thickness direction of the substrate, and is a flip chip type micro light emitting diode.

According to one or more embodiments of the present disclosure, there is provided a display device including a substrate, a plurality of electrode pads including a first electrode pad and a common electrode pad on the substrate, a light emitting element including a first contact electrode on the first electrode pad and a second contact electrode on the common electrode pad, a conductive adhesive member including a plurality of conductive balls connecting the first electrode pad and the first contact electrode and connecting the common electrode pad and the second contact electrode, and a dielectric layer on the substrate between the first electrode pad and the common electrode pad in a plan view, the dielectric layer having a reverse taper shape having a lateral inclination in which a length decreases from a top surface to a bottom surface.

According to one or more embodiments of the present disclosure, there is provided a tiled display device including a plurality of display devices and a seam located between the plurality of display devices. A first display device from among the plurality of display devices includes a substrate, a plurality of electrode pads including a first electrode pad and a common electrode pad on a first surface of the substrate, a light emitting element including a first contact electrode on the first electrode pad and a second contact electrode on the common electrode pad, a conductive adhesive member including a plurality of conductive balls connecting the first electrode pad and the first contact electrode and connecting the common electrode pad and the second contact electrode, and a plurality of protrusions on the substrate and protruding in a thickness direction of the substrate. First protrusions from among the plurality of protrusions overlap the electrode pads in the thickness direction of the substrate.

The light emitting element may be a flip chip type micro light emitting diode.

The substrate may include glass.

The first display device may further include a pad on the first surface of the substrate, and a side line on the first surface of the substrate, a second surface opposite to the first surface, and one side surface between the first surface and the second surface, and connected to the pad.

The first display device may further include a connection line on the second surface of the substrate, and a flexible film connected to the connection line through the conductive adhesive member. The side line may be connected to the connection line.

The plurality of display devices may be arranged in a matrix form in M rows and N columns.

According to the aforementioned and other embodiments of the present disclosure, the display device may include a plurality of protrusions overlapping electrode pads or located between the electrode pads. Because the plurality of protrusions may suppress the flow of the conductive ball, it is possible to suppress occurrence of dark spots or short circuit defects of the display device.

According to the aforementioned and other embodiments of the present disclosure, the electrode pads may include a recess recessed in a part of the top surface of the electrode pad to fix the conductive balls. The recess may suppress the flow of the conductive ball, and increase or maximize the contact area and density of the conductive ball. Accordingly, an image quality may be improved by optimizing the current injection efficiency of the display device.

According to the aforementioned and other embodiments of the present disclosure, poor connection between the electrode pads may be suppressed, so that an ultra-high resolution display device may be realized by reducing the gap between the electrode pads.

### BRIEF DESCRIPTION OF THE DRAWINGS

The above and other embodiments and features of the present disclosure will become more apparent by describing embodiments thereof with reference to the attached drawings, in which:

FIG. 1 is a perspective view illustrating a front surface of a display device according to one or more embodiments;

FIG. 2 is a perspective view illustrating a rear surface of the display device according to one or more embodiments;

FIG. 3 is a diagram illustrating an example of a pixel of a display device according to one or more embodiments;

FIG. 4 is a diagram illustrating an example of a pixel of a display device according to one or more embodiments;

FIG. 5 is a diagram illustrating an example of a pixel of a display device according to one or more embodiments;

FIG. 6 is a diagram illustrating a conductive adhesive member in which conductive balls are included in the pixel of FIG. 5;

FIG. 7 is an example of an enlarged plan view of an area X of FIG. 6;

FIG. 8 is an example of the enlarged plan view of the area X of FIG. 6;

FIG. 9 is an example of the enlarged plan view of the area X of FIG. 6;

FIG. 10 shows an example of a cross-sectional structure of a pixel taken along the line A-A′ of FIG. 6;

FIG. 11 is an example of a cross-sectional view taken along the line B-B′ of FIG. 7;

FIG. 12 is an example of a cross-sectional view taken along the line B-B′ of FIG. 7;

FIG. 13 is an example of a cross-sectional view taken along the line C-C′ of FIG. 8;

FIG. 14 is an enlarged plan view of a pixel of a display device according to one or more embodiments;

FIG. 15 is an example of a cross-sectional view taken along the line D-D′ of FIG. 14;

FIG. 16 is an enlarged plan view of a pixel of a display device according to one or more embodiments;

FIG. 17 is an example of a cross-sectional view taken along the line E-E′ of FIG. 16;

FIG. 18 is an enlarged cross-sectional view of a pad metal layer and a light emitting element of FIG. 17;

FIG. 19 is an enlarged plan view of a pixel of a display device according to one or more embodiments;

FIG. 20 is a cross-sectional view illustrating a pad metal layer and a light emitting element taken along the line F-F′ of FIG. 19;

FIG. 21 is a perspective view illustrating in detail one edge of a display device according to one or more embodiments;

FIG. 22 is a plan view illustrating an arrangement relationship between a pixel and a side line of a display device according to one or more embodiments;

FIG. 23 is a rear view illustrating an arrangement relationship between a pixel and a side line of a display device according to one or more embodiments;

FIG. 24 is a cross-sectional view taken along the line G-G′ of FIG. 23;

FIG. 25 is a perspective view illustrating a tiled display device including a plurality of display devices according to one or more embodiments;

FIG. 26 is an enlarged view of an area E of FIG. 25;

FIG. 27 is a cross-sectional view illustrating an example of a tiled display device taken along the line X1-X1′ of FIG. 26; and

FIG. 28 is a block diagram illustrating a tiled display device according to one or more embodiments.

### DETAILED DESCRIPTION

Aspects and features of embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure might not be described.

Unless otherwise noted, like reference numerals, characters, or combinations thereof denote like elements throughout the attached drawings and the written description, and thus, descriptions thereof will not be repeated. Further, parts not related to the description of one or more embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the particular illustrated shapes of regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions such as “at least one of,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, YZ, and ZZ, or any variation thereof. Similarly, the expression such as “at least one of A and B” may include A, B, or A and

B. As used herein, the term “and/or” includes any and all combinations of one or more of the associated listed items. For example, the expression such as “A and/or B” may include A, B, or A and B.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The electronic or electric devices and/or any other relevant devices or components according to embodiments of the present disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of embodiments of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

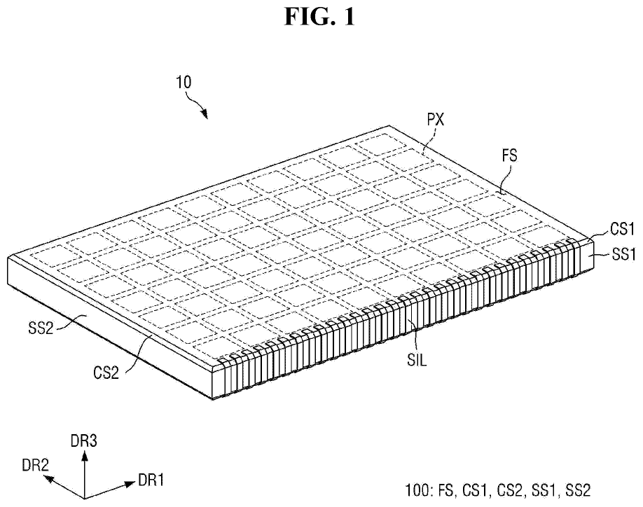

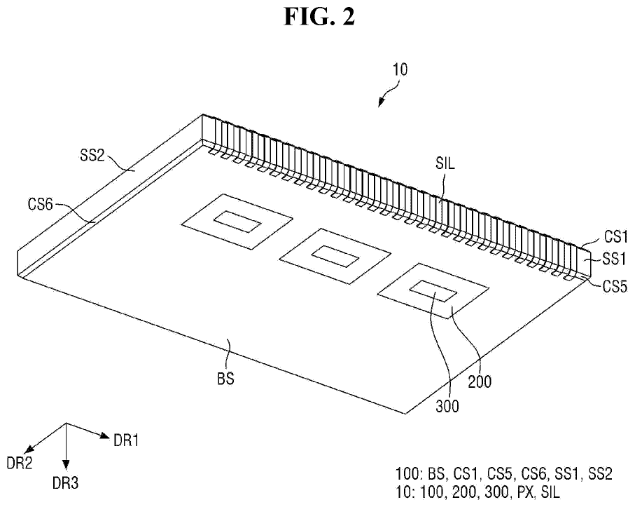

FIG. 1 is a perspective view illustrating a front surface of a display device according to one or more embodiments. FIG. 2 is a perspective view illustrating a rear surface of the display device according to one or more embodiments.

In FIGS. 1 and 2, a first direction DR1, a second direction DR2, and a third direction DR3 are illustrated. The first direction DR1 indicates a horizontal direction of the display device 10, the second direction DR2 indicates a vertical direction of the display device 10, and the third direction DR3 indicates a thickness direction of the display device 10. In this case, “left”, “right”, “upper” and “lower” indicate directions when the display device 10 is viewed from above. For example, “right side” indicates one side of the first direction DR1, “left side” indicates the other side of the first direction DR1, “upper side” indicates one side of the second direction DR2, and “lower side” indicates the other side of the second direction DR2. Further, “upper portion” indicates one side of the third direction DR3, and “lower portion” indicates the other side of the third direction DR3. “Upper portion” may be referred to as one surface, a front surface, or a first surface of the display device 10, and “lower portion” may be referred to as the other surface, a rear surface, or a second surface of the display device 10.

Referring to FIGS. 1 to 2, a display device 10 is a device for displaying a moving image or a still image. The display device 10 may be used as a display screen of various devices, such as a television, a laptop computer, a monitor, a billboard and an Internet-of-Things (IOT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

The display device 10 may have a planar shape similar to a quadrilateral shape. For example, the display device 10 may have a planar shape similar to a quadrilateral shape having long sides in the first direction DR1 and short sides in the second direction DR2, as shown in FIG. 1. A corner where the long side in the first direction DR1 and the short side in the second direction DR2 meet may be right-angled or rounded with a suitable curvature (e.g., a predetermined curvature). The planar shape of the display device 10 is not limited to a quadrilateral shape, and may be formed in a shape similar to another polygonal shape, a circular shape, or elliptical shape.

The display device 10 according to one or more embodiments may include a substrate 100, a plurality of pixels PX, a plurality of side lines SIL, a circuit board 200, and a display driving circuit 300.

The substrate 100 may serve as a base of the display device 10. The substrate 100, which has a three-dimensional shape similar to a rectangular parallelepiped, may include a front surface, side surfaces, and a rear surface. The substrate 100 may have a shape in which corners formed by the front surface and the side surfaces and corners formed by the rear surface and the side surfaces are bent. For example, the substrate 100 may include chamfered surfaces formed by bending the corners.

The substrate 100 may include a first surface FS, a second surface BS, a plurality of side surfaces, and a plurality of chamfered surfaces.

The first surface FS may be the front surface of the substrate 100. The first surface FS may have a rectangular shape having long sides in the first direction DR1 and short sides in the second direction DR2.

The second surface BS may be a surface opposite to the first surface FS in the third direction DR3. The second surface BS may be the rear surface of the substrate 100. The second surface BS may have a rectangular shape having long sides in the first direction DR1 and short sides in the second direction DR2.

The plurality of side surfaces, which are disposed between the first surface FS and the second surface BS, may be the side surfaces of the substrate 100. A first side surface SS1 may be a side surface extending from the lower side (the other side in the second direction DR2) of the first surface FS from among the plurality of side surfaces. A second side surface SS2 may be a side surface extending from the left side (the other side in the first direction DR1) of the first surface FS from among the plurality of side surfaces. From among the plurality of side surfaces, a side surface extending from the upper side (one side in the second direction DR2) of the first surface FS may be referred to as “third side surface,” and a side surface extending from the right side (one side in the first direction DR1) of the first surface FS may be referred to as “fourth side surface.”

The plurality of chamfered surfaces may refer to surfaces that are disposed between the first surface FS and the plurality of side surfaces and between the second surface BS and the plurality of side surfaces and are obliquely cut to prevent occurrence of chipping defects in the plurality of side lines SIL. Due to the plurality of chamfered surfaces, it is possible to prevent occurrence of chipping or crack in the plurality of side lines SIL.

A first chamfered surface CS1 may be disposed between the first surface FS and the first side surface SS1. A second chamfered surface CS2 may be disposed between the first surface FS and the second side surface SS2. A third chamfered surface may be disposed between the first surface FS and the third side surface. A fourth chamfered surface may be disposed between the first surface FS and the fourth side surface. Each of the internal angle formed by the first surface FS and the first chamfered surface CS1, the internal angle formed by the first surface FS and the second chamfered surface CS2, the internal angle formed by the first surface FS and the third chamfered surface, and the internal angle formed by the first surface FS and the fourth chamfered surface may be greater than 90 degrees.

A fifth chamfered surface CS5 may be disposed between the second surface BS and the first side surface SS1. A sixth chamfered surface CS6 may be disposed between the second surface BS and the second side surface SS2. A seventh chamfered surface may be disposed between the second surface BS and the third side surface. An eighth chamfered surface may be disposed between the second surface BS and the fourth side surface. Each of the internal angle formed by the second surface BS and the fifth chamfered surface CS5, the internal angle formed by the second surface BS and the sixth chamfered surface CS6, the internal angle formed by the second surface BS and the seventh chamfered surface, and the internal angle formed by the second surface BS and the eighth chamfered surface may be greater than 90 degrees.

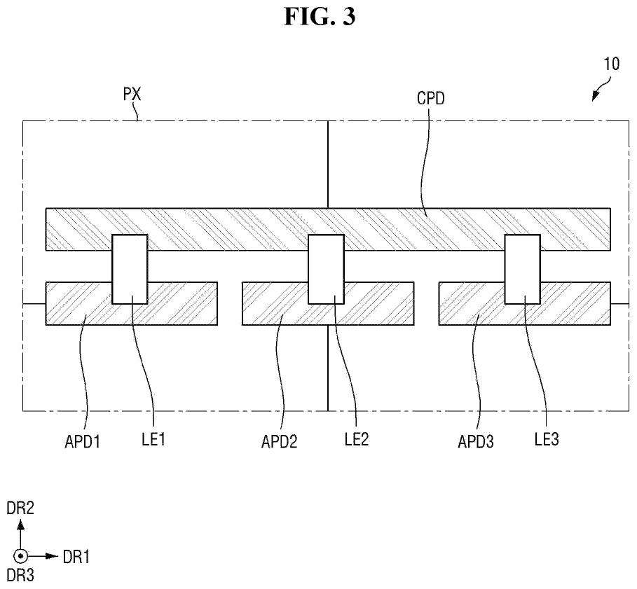

The plurality of pixels PX may be disposed on the first surface FS of the substrate 100 to display an image. The plurality of pixels PX may be arranged in a matrix form in the first direction DR1 and the second direction DR2. For example, the plurality of pixels PX may be arranged along rows and columns of a matrix along the first direction DR1 and the second direction DR2. The plurality of pixels PX will be described in detail later in conjunction with FIGS. 3 to 5.

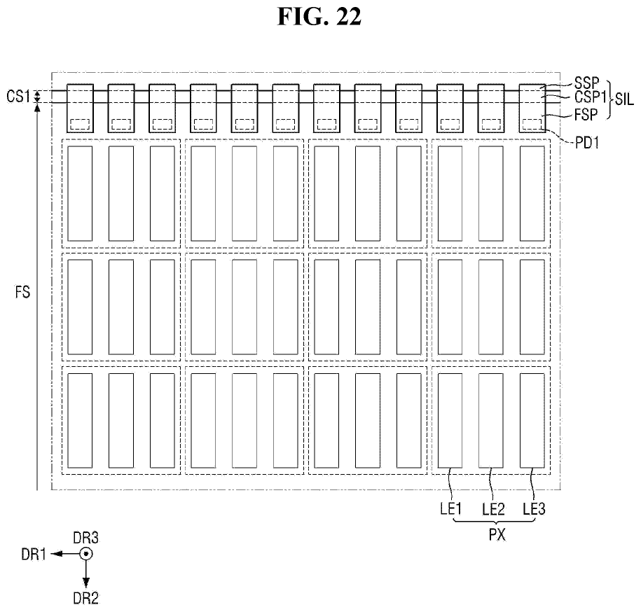

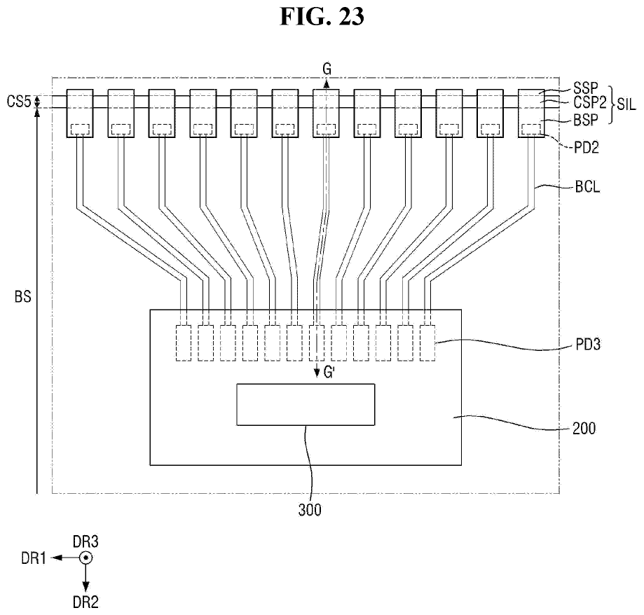

Each of the plurality of side lines SIL serves to connect a first pad PD1 (see FIG. 22) disposed on the first surface FS, e.g., a front surface pad, and a second pad PD2 (see FIG. 23) disposed on the second surface BS, e.g., a rear surface pad. The first pads PD1 may be connected to data lines connected to the pixels PX of the substrate 100.

The plurality of side lines SIL may be disposed on the first surface FS, the second surface BS, at least any two chamfered surfaces from among the plurality of chamfered surfaces, and at least any one side surface from among the plurality of side surfaces. For example, the plurality of side lines SIL may be disposed on the first surface FS, the second surface BS, the first chamfered surface CS1, the fifth chamfered surface CS5, and the first side surface SS1 in order to connect the first pads PD1 (see FIG. 22) disposed on a first side (the other side of the second direction DR2 in FIG. 1) of the first surface FS and the second pads PD2 (see FIG. 23) disposed on a first side (one side of the second direction DR2 in FIG. 2) of the second surface BS.

In one or more embodiments, when the first pads PD1 disposed on a second side (the other side of the first direction DR1 in FIG. 1) of the first surface FS and the second pads PD2 disposed on a second side (one side of the first direction DR1 in FIG. 2) of the second surface BS are further included, the plurality of side lines SIL may be further disposed on the first surface FS, the second surface BS, the second chamfered surface CS2, the sixth chamfered surface CS6, and the second side surface SS2.

The circuit boards 200 may be disposed on the second surface BS of the substrate 100. Each of the circuit boards 200 may be connected to third pads PD3 (see FIG. 23) disposed on the second surface BS of the substrate 100 using a conductive adhesive member such as an anisotropic conductive film (ACF). As will be described later in FIG. 23, the third pads PD3 are electrically connected to the second pads PD2, respectively, so that the circuit board 200 may be electrically connected to the first pads PD1 through the side lines SIL. The circuit boards 200 may each be a flexible printed circuit board, a printed circuit board, or a flexible film such as a chip on film.

The display driving circuit 300 may generate data voltages and supply the data voltages to the data lines through the circuit board 200, the third pads PD3 (see FIG. 23), the second pads PD2 (see FIG. 23), the plurality of side lines SIL, and the first pads PD1 (see FIG. 22). The display driving circuit 300 may be formed as an integrated circuit (IC) and attached onto the circuit board 200. Alternatively, the display driving circuit 300 may be directly attached to the second surface BS of the substrate 100 by a chip on glass (COG) method.

The flexible film bent along the side surface of the substrate 100 may be eliminated by connecting the first pads PD1 (see FIG. 22) disposed on the first surface FS and the second pads PD2 (see FIG. 23) disposed on the second surface BS using the plurality of side lines SIL as shown in FIG. 1. Accordingly, a bezel-less display device may be implemented.

Hereinafter, the structure of the pixel PX of the display device 10 according to one or more embodiments will be described.

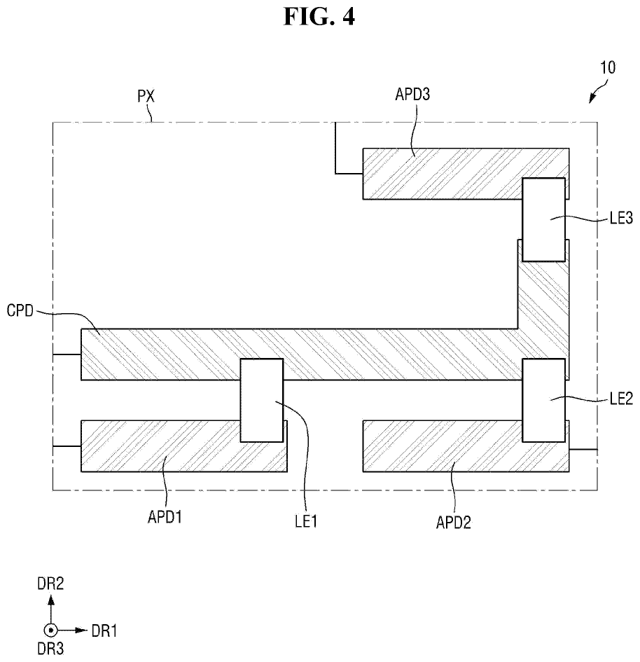

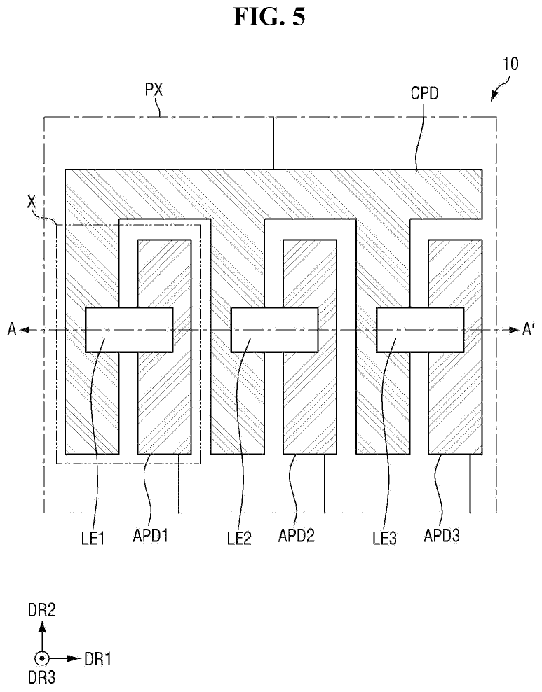

FIG. 3 is a diagram illustrating an example of a pixel of a display device according to one or more embodiments. FIG. 4 is a diagram illustrating an example of a pixel of a display device according to one or more embodiments. FIG. 5 is a diagram illustrating an example of a pixel of a display device according to one or more embodiments.

Referring to FIGS. 3 to 5, each of the pixels PX may include a plurality of light emitting elements LE1, LE2, and LE3. Although FIGS. 3 to 5 illustrate that each of the pixels PX includes three light emitting elements LE1, LE2, and LE3, i.e., a first light emitting element LE1, a second light emitting element LE2, and a third light emitting element LE3, the present disclosure is not limited thereto. Each of the first light emitting element LE1, the second light emitting element LE2, and the third light emitting element LE3 may be connected to any one of the data lines and at least one of scan lines through first to third electrode pads APD1, APD2, and APD3. Each of the first light emitting element LE1, the second light emitting element LE2, and the third light emitting element LE3 may be electrically connected to a constant potential line through a common electrode pad CPD.

Each of the first light emitting element LE1, the second light emitting element LE2, and the third light emitting element LE3, which is a light emitting element emitting light, may be an inorganic light emitting element including an inorganic semiconductor. For example, the inorganic light emitting element may be a flip chip type micro light emitting diode (LED), but the present disclosure is not limited thereto.

The first light emitting element LE1 may emit first light, the second light emitting element LE2 may emit second light, and the third light emitting element LE3 may emit third light. Here, the first light may be light of a red wavelength band, the second light may be light of a green wavelength band, and the third light may be light of a blue wavelength band. Although the red wavelength band may be a wavelength band of about 600 nm to 750 nm, the green wavelength band may be a wavelength band of about 480 nm to 560 nm, and the blue wavelength band may be a wavelength band of about 370 nm to 460 nm, the present disclosure is not limited thereto.

Each of the first light emitting element LE1, the second light emitting element LE2, and the third light emitting element LE3 may have a rectangular or square planar shape in a plan view. For example, each of the first light emitting element LE1, the second light emitting element LE2, and the third light emitting element LE3 may have a rectangular planar shape having short sides in the first direction DR1 and long sides in the second direction DR2 as shown in FIGS. 3 and 4. Alternatively, each of the first light emitting element LE1, the second light emitting element LE2, and the third light emitting element LE3 may have a rectangular planar shape having long sides in the first direction DR1 and short sides in the second direction DR2 as shown in FIG. 5.

As shown in FIGS. 3 and 5, the first light emitting element LE1, the second light emitting element LE2, and the third light emitting element LE3 may be arranged along the first direction DR1. Alternatively, the second light emitting element LE2 and any one of the first light emitting element LE1 and the third light emitting element LE3 may be arranged along the first direction DR1, and the second light emitting element LE2 and the other one of the first light emitting element LE1 and the third light emitting element LE3 may be arranged along the second direction DR2. For example, the second light emitting element LE2 and the first light emitting element LE1 may be arranged along the first direction DR1, and the second light emitting element LE2 and the third light emitting element LE3 may be arranged along the second direction DR2.

The first light emitting element LE1, the second light emitting element LE2, and the third light emitting element LE3 may be connected to the first electrode pad APD1, the second electrode pad APD2, and the third electrode pad APD3 corresponding thereto, respectively, and may be commonly connected to the common electrode pad CPD. For example, the first light emitting element LE1 may be connected to the first electrode pad APD1 and the common electrode pad CPD, the second light emitting element LE2 may be connected to the second electrode pad APD2 and the common electrode pad CPD, and the third light emitting element LE3 may be connected to the third electrode pad APD3 and the common electrode pad CPD. Hereinafter, the first to third electrode pads APD1, APD2, and APD3 and the common electrode pad CPD may be collectively referred to as “electrode pad.”

Each of the first to third light emitting elements LE1, LE2, and LE3 may be connected to a plurality of driving circuits in the pixel PX to form a sub-pixel. For example, the first light emitting element LE1 may be connected to the plurality of driving circuits through the first electrode pad APD1 and the common electrode pad CPD to form a first sub-pixel. The second light emitting element LE2 may be connected to the plurality of driving circuits through the second electrode pad APD2 and the common electrode pad CPD to form a second sub-pixel. The third light emitting element LE3 may be connected to the plurality of driving circuits through the third electrode pad APD3 and the common electrode pad CPD to form a third sub-pixel.

Each of the first to third electrode pads APD1, APD2, and APD3 and the common electrode pad CPD may have a quadrilateral planar shape, or may have another polygonal shape, a circular shape, or a shape similar thereto. For example, each of the first to third electrode pads APD1, APD2, and APD3 and the common electrode pad CPD may have a rectangular planar shape having long sides in the first direction DR1 and short sides in the second direction DR2 as shown in FIG. 3. Alternatively, as shown in FIG. 4, each of the first to third electrode pads APD1, APD2, and APD3 may have a rectangular planar shape having long sides in the first direction DR1 and short sides in the second direction DR2, and the common electrode pad CPD may have an approximately L-shaped arrangement. Alternatively, as shown in FIG. 5, each of the first to third electrode pads APD1, APD2, and APD3 may have a rectangular planar shape having short sides in the first direction DR1 and long sides in the second direction DR2, and the common electrode pad CPD may have a polygonal planar shape having a stem portion extending in the first direction DR1 and a plurality of branch portions branched from the stem portion and extending in the second direction DR2.

The first to third electrode pads APD1, APD2, and APD3 and the common electrode pad CPD may be arranged along the first direction DR1 or the second direction DR2 in consideration of the arrangement of the first light emitting element LE1, the second light emitting element LE2, and the third light emitting element LE3. For example, each of the first to third electrode pads APD1, APD2, and APD3 and the common electrode pad CPD may be arranged along the second direction DR2 as shown in FIG. 3. Alternatively, as shown in FIG. 5, each of the first to third electrode pads APD1, APD2, and APD3 and the stem portions of the common electrode pad CPD may be arranged along the first direction DR1.

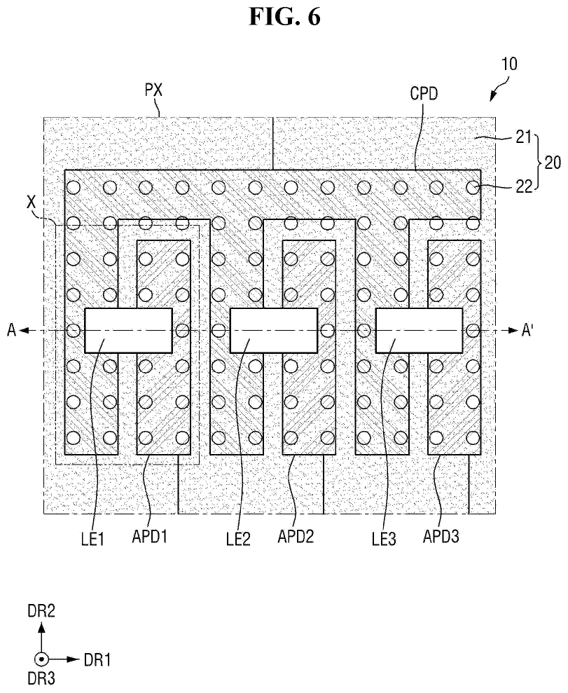

FIG. 6 is a diagram illustrating a conductive adhesive member in which conductive balls are included in the pixel of FIG. 5.

Referring to FIG. 6, the display device 10 according to one or more embodiments may include a conductive adhesive member 20 to attach the plurality of light emitting elements LE1, LE2, and LE3 to the electrode pads.

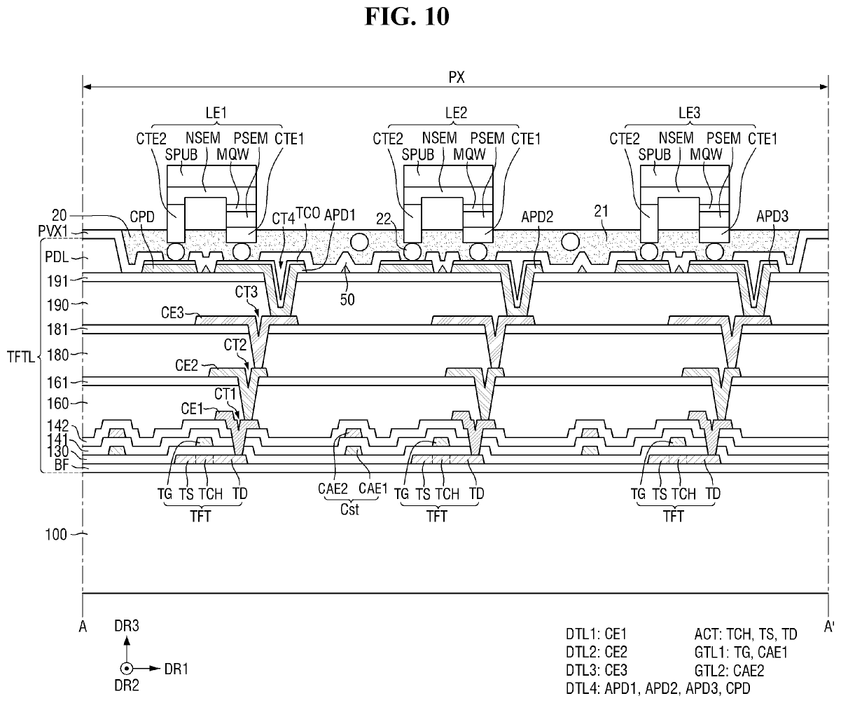

The conductive adhesive member 20 may be an adhesive layer for fixing the plurality of light emitting elements LE1, LE2, and LE3 and connecting the plurality of light emitting elements LE1, LE2, and LE3 and the substrate 100 (see FIG. 10) of the display device 10. In one or more embodiments, due to the conductive adhesive member 20, the first light emitting element LE1 may be adhered to the first electrode pad APD1 and the common electrode pad CPD, the second light emitting element LE2 may be adhered to the second electrode pad APD2 and the common electrode pad CPD, and the third light emitting element LE3 may be adhered to the third electrode pad APD3 and the common electrode pad CPD.

The conductive adhesive member 20 may be an anisotropic conductive film (ACF) or an anisotropic conductive paste (ACP). Hereinafter, a case where the conductive adhesive member 20 is an anisotropic conductive film will be illustrated, but the present disclosure is not limited thereto.

The conductive adhesive member 20 may be a double-sided adhesive film formed by mixing an adhesive resin 21 cured by heat and conductive balls 22 having a fine particle size.

The adhesive resin 21 may be coated on the entire or partial surface of the display device 10. The adhesive resin 21 may be a sheet-type adhesive including a resin, but the present disclosure is not limited thereto. The adhesive resin 21 may have fluidity at a high temperature.

The conductive balls 22 may be dispersed in the adhesive resin 21. The conductive balls 22 may be disposed at equal intervals along the first direction DR1 and the second direction DR2 as shown in FIG. 6, but the present disclosure is not limited thereto and the conductive balls 22 may be irregularly disposed. For another example, the conductive balls 22 may be concentrated at a high density only around the electrode pad. The conductive ball 22 may be a sphere or an ellipsoid having a circular or elliptical shape in a plan view. The conductive ball 22 may have a size of 3 μm to 5 μm. The distance between the conductive ball 22 may be 50 μm or less. The conductive balls 22, which are metal particles having conductivity, may include copper (Cu), nickel (Ni), gold (Au), silver (Ag), or the like.

At least some of the plurality of conductive balls 22 may overlap between the light emitting elements LE1, LE2, and LE3 and the electrode pad in the third direction DR3. In this case, the conductive ball 22 connects the light emitting elements LE1, LE2, and LE3 and the electrode pad, so that the display device 10 may have conductivity in the third direction DR3. In one or more embodiments, some others of the plurality of conductive balls 22 may not overlap the light emitting elements LE1, LE2, and LE3 in the third direction DR3. The conductive balls 22 may be disposed around the light emitting elements LE1, LE2, and LE3. In this case, the conductive ball 22 does not serve as an electrical medium, so that the display device 10 may have an insulating property in the first direction DR1 and the second direction DR2.

In one or more embodiments, after the conductive adhesive member 20 is attached to the front surface of the substrate 100 (see FIG. 10) on which the first to third electrode pads APD1, APD2, and APD3 and the common electrode pad CPD are formed, flip chip type light emitting elements LE1, LE2, and LE3 may be positioned. When heat and pressure are applied, the conductive adhesive member 20 may connect the electrode pads of the substrate 100 and the plurality of light emitting elements LE1, LE2, and LE3. The first to third electrode pads APD1, APD2, and APD3 and the common electrode pad CPD may be electrically connected to the plurality of light emitting elements LE1, LE2, and LE3 through conductive balls 22.

In the connection process, the adhesive resin 21 of the conductive adhesive member 20 may have fluidity due to the heat and pressure. When the conductive balls 22 are moved without being fixed due to the fluidity of the adhesive resin 21, poor connection between the light emitting elements LE1, LE2, and LE3 and the electrode pads may occur. For example, the conductive balls 22 electrically connecting the light emitting elements LE1, LE2, and LE3 and the electrode pads may be moved out of the electrode pad. The light emitting elements LE1, LE2, and LE3 that are not connected to the electrode pads may cause dark spots, or the moved conductive balls 22 may cause an electrical short circuit by connecting the first to third electrode pads APD1, APD2, and APD3 and the common electrode pad CPD.

The display device 10 according to one or more embodiments may include a plurality of protrusions 50 (see FIG. 10) protruding from the substrate 100 (see FIG. 10). The plurality of protrusions 50 may suppress the movement of the conductive balls 22 of the conductive adhesive member 20 to the outside of the electrode pad. Because the conductive balls 22 are fixed by the plurality of protrusions 50, poor connection between the light emitting elements LE1, LE2, and LE3 and the electrode pads may be suppressed. The occurrence of dark spots or electrical short circuit of the display device 10 may be suppressed.

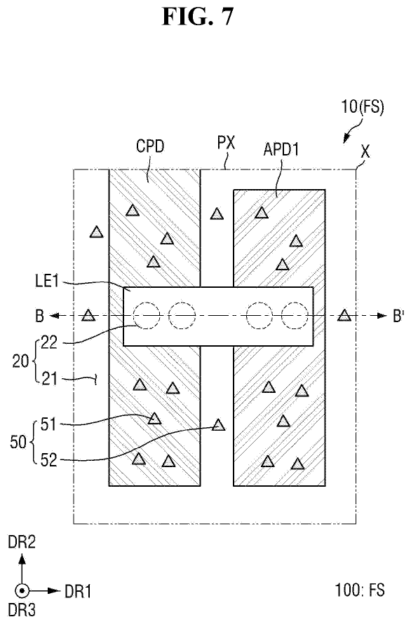

Hereinafter, embodiments of the display device 10 including the plurality of protrusions 50 will be described with reference to FIGS. 7 to 9.

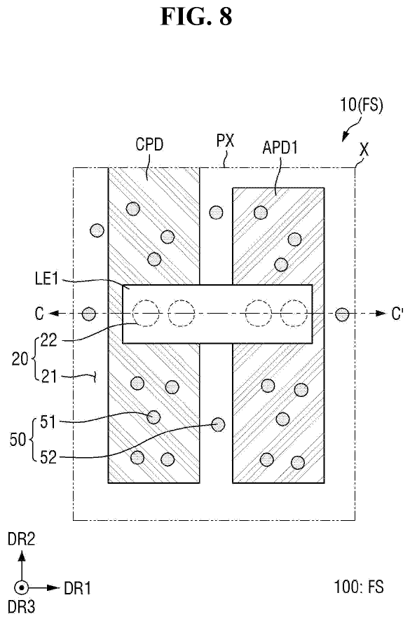

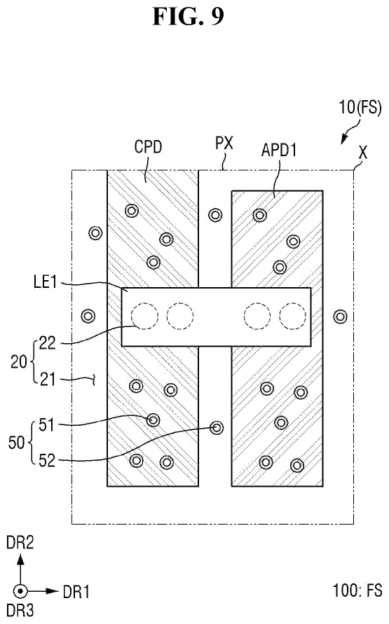

FIG. 7 is an example of an enlarged plan view of an area X of FIG. 6. FIG. 8 is an example of the enlarged plan view of the area X of FIG. 6. FIG. 9 is an example of the enlarged plan view of the area X of FIG. 6.

FIGS. 7 to 9 illustrate the first light emitting element LE1 of the pixel PX, and the first electrode pad APD1 and the common electrode pad CPD connected thereto. The conductive balls 22 formed between the first light emitting element LE1 and the first electrode pad APD1 and between the first light emitting element LE1 and the common electrode pad CPD are illustrated by dotted lines. Although the illustration of the conductive ball 22 formed outside the first electrode pad APD1 and the common electrode pad CPD is omitted, the conductive ball 22 may also be formed outside the first electrode pad APD1 and the common electrode pad CPD as shown in FIG. 6.

The display device 10 according to one or more embodiments may include the plurality of protrusions 50 protruding from the first surface FS that is the front surface of the substrate. The plurality of protrusions 50 may be irregularly distributed along the first direction DR1 and the second direction DR2.

The plurality of protrusions 50 may overlap the electrode pads in the third direction DR3, or may be formed between the electrode pads. For example, from among the plurality of protrusions 50, first protrusions 51 may overlap the electrode pads in the third direction DR3, and may overlap the electrode pads above or below the electrode pads. Some of the first protrusions 51 may overlap the first electrode pad APD1 above or below the first electrode pad APD1, and some others of the first protrusions 51 may overlap the common electrode pad CPD above or below the common electrode pad CPD. For another example, from among the plurality of protrusions 50, second protrusions 52 may be formed between the electrode pads.

The second protrusions 52 may be formed between the first electrode pad APD1 and the common electrode pad CPD, or may be formed outside the first electrode pad APD1 or the common electrode pad CPD.

The plurality of protrusions 50 may have a polygonal shape such as a triangular shape and a quadrangular shape, or a circular shape, an oval shape, and a donut shape in a plan view. The plurality of protrusions 50 may have a shape protruding from the first surface FS, for example, a tetrahedron shape such as a triangular pyramid and a quadrangular pyramid, a conical structure, a hexahedron shape, a hemispherical structure, a semielliptical structure, or a donut structure having a central opening. FIG. 7 illustrates the protrusions 50 having a tetrahedron shape.

FIG. 8 illustrates the protrusions 50 having a hemispherical structure, a semielliptical structure, a conical structure, or a cylindrical (or columnar) structure. FIG. 9 illustrates the protrusions 50 having a donut structure whose inner diameter and outer diameter are different due to the central opening. However, the shapes of the protrusions 50 according to the embodiments are not limited thereto.

The plurality of protrusions 50 may have a smaller size than the conductive ball 22. For example, the maximum length of the protrusion 50 may be 0.5 μm to 1.5 μm. The diameter of the conductive ball 22 may be 3 μm to 5 μm. The plurality of protrusions 50 may be formed adjacent to the conductive ball 22 to prevent the conductive balls 22 from being moved by the fluidity of the adhesive resin 21. For example, the conductive balls 22 may be surrounded by the protrusions 50 in a plan view. In other words, the conductive balls 22 may be surrounded by the protrusions 50.

The second light emitting element LE2 and the third light emitting element LE3 according to one or more embodiments may be substantially the same as the first light emitting element LE1 described in conjunction with FIGS. 7 to 9. Therefore, the description of the second light emitting element LE2 and the third light emitting element LE3 according to one or more embodiments will be omitted.

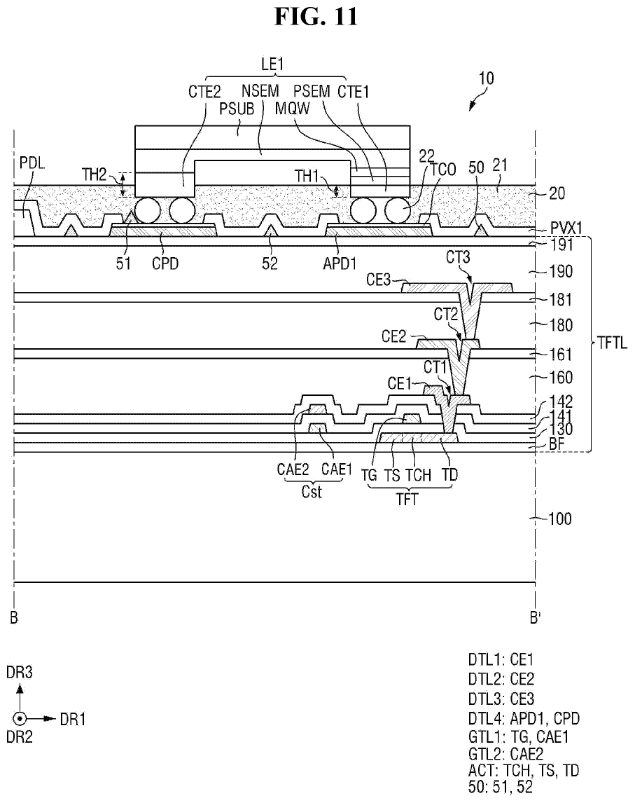

FIG. 10 shows an example of a cross-sectional structure of a pixel taken along the line A-A′ of FIG. 6. FIG. 11 is an example of a cross-sectional view taken along the line B-B′ of FIG. 7. FIG. 10 is a cross-sectional view of the pixel PX including the first light emitting element LE1, the first electrode pad APD1, the second light emitting element LE2, the second electrode pad APD2, the third light emitting element LE3, the third electrode pad APD3, and the common electrode pad CPD, and FIG. 11 is a cross-sectional view illustrating in detail the first light emitting element LE1, the first electrode pad APD1, the common electrode pad CPD, and the protrusions 50.

Referring to FIGS. 10 and 11, each of the plurality of sub-pixels constituting the pixel PX may include a thin film transistor layer TFTL and the light emitting elements LE1, LE2, and LE3 disposed on the substrate 100. The thin film transistor layer TFTL, which includes a plurality of conductive layers and a plurality of insulating layers, may be a layer on which thin film transistors TFT transmitting electrical signals of the light emitting elements LE1, LE2, and LE3 are formed.

The thin film transistor layer TFTL includes, as the conductive layers, an active layer ACT, a first gate layer GTL1, a second gate layer GTL2, a first data metal layer DTL1, a second data metal layer DTL2, a third data metal layer DTL3, and a fourth data metal layer DTL4. Further, the thin film transistor layer TFTL includes, as the insulating layers, a buffer layer BF, a gate insulating layer 130, a first interlayer insulating layer 141, a second interlayer insulating layer 142, a first planarization layer 160, a first insulating layer 161, a second planarization layer 180, a second insulating layer 181, a third planarization layer 190, and a third insulating layer 191. Further, the thin film transistor layer TFTL includes a pixel defining layer PDL and a first passivation layer PVX1 formed on the third insulating layer 191.

The substrate 100 may be a base substrate or a base member for supporting the display device 10. The substrate 100 may be a rigid substrate made of glass, but the present disclosure is not limited thereto. The substrate 100 may be a flexible substrate which can be bent, folded or rolled. In this case, the substrate 100 may include an insulating material such as a polymer resin such as polyimide (PI).

The buffer layer BF may be disposed on one surface of the substrate 100. The buffer layer BF may be a layer for preventing permeation of air or moisture. The buffer layer BF may be formed of a plurality of inorganic layers that are alternately stacked. For example, the buffer layer BF may be formed of multiple layers in which one or more inorganic layers of a silicon nitride layer, a silicon oxynitride layer, a silicon oxide layer, a titanium oxide layer and an aluminum oxide layer are alternately stacked. The buffer layer BF may be omitted.

The active layer ACT may be disposed on the buffer layer BF. The active layer ACT may include a silicon semiconductor such as polycrystalline silicon, monocrystalline silicon, low-temperature polycrystalline silicon, and amorphous silicon, or may include an oxide semiconductor.

The active layer ACT may include a channel TCH, a first electrode TS, and a second electrode TD of the thin film transistor TFT. The channel TCH of the thin film transistor TFT may be a region overlapping a gate electrode TG of the thin film transistor TFT in the third direction DR3 that is the thickness direction of the substrate 100. The first electrode TS of the thin film transistor TFT may be disposed on one side of the channel TCH, and the second electrode TD may be disposed on the other side of the channel TCH. The first electrode TS and the second electrode TD of the thin film transistor TFT may be regions that do not overlap the gate electrode TG in the third direction DR3. The first electrode TS and the second electrode TD of the thin film transistor TFT may be conductive regions obtained by doping a silicon semiconductor or an oxide semiconductor with ions.

The gate insulating layer 130 may be disposed on the active layer ACT and the buffer layer BF. The gate insulating layer 130 may be formed of an inorganic layer, for example, a silicon nitride layer, a silicon oxynitride layer, a silicon oxide layer, a titanium oxide layer, or an aluminum oxide layer.

The first gate layer GTL1 may be disposed on the gate insulating layer 130. The first gate layer GTL1 may include the gate electrode TG of the thin film transistor TFT and a first capacitor electrode CAE1. The first gate layer GTL1 may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

The first interlayer insulating layer 141 may be disposed on the first gate layer GTL1 and the gate insulating layer 130. The first interlayer insulating layer 141 may be formed of an inorganic layer, for example, a silicon nitride layer, a silicon oxynitride layer, a silicon oxide layer, a titanium oxide layer, or an aluminum oxide layer.

The second gate layer GTL2 may be disposed on the first interlayer insulating layer 141. The second gate layer GTL2 may include a second capacitor electrode CAE2. The second capacitor electrode CAE2 with the first capacitor electrode CAE1 may form a capacitor Cst while using the first interlayer insulating layer 141 as a dielectric. The second gate layer GTL2 may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

The second interlayer insulating layer 142 may be disposed on the second gate layer GTL2 and first interlayer insulating layer 141. The second interlayer insulating layer 142 may be formed of an inorganic layer, for example, a silicon nitride layer, a silicon oxynitride layer, a silicon oxide layer, a titanium oxide layer, or an aluminum oxide layer.

The first data metal layer DTL1 may be disposed on the second interlayer insulating layer 142. The first data metal layer DTL1 may include a first connection electrode CE1. The first connection electrode CE1 may be connected to the second electrode TD of the thin film transistor TFT through a first contact hole CT1 penetrating the gate insulating layer 130, the first interlayer insulating layer 141, and the second interlayer insulating layer 142. The present disclosure is not limited thereto, and the first connection electrode CE1 may be connected to the first electrode TS.

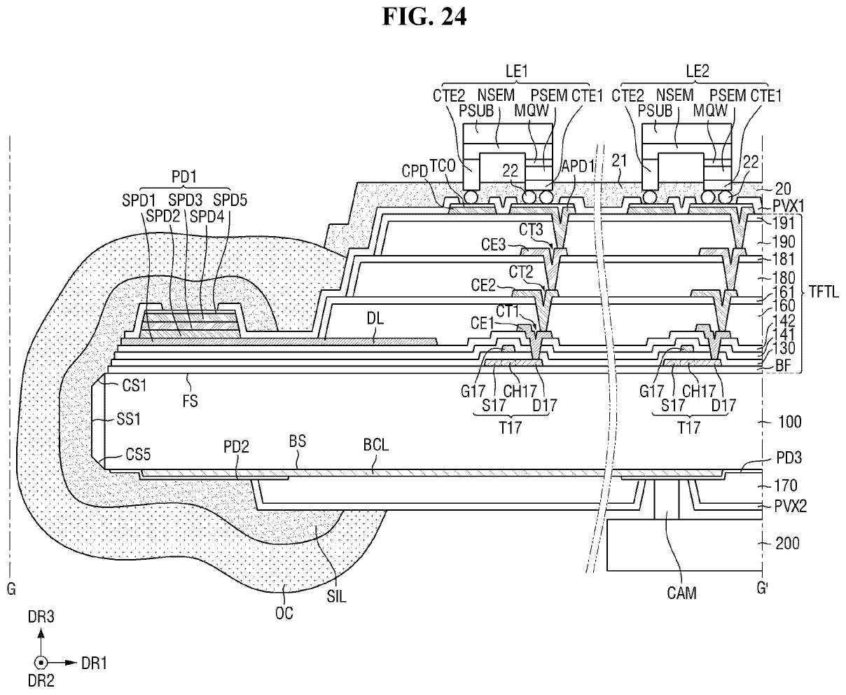

The first data metal layer DTL1 may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof. As will be described later, the first data metal layer DTL1 may further include a first sub-pad SPD1 (see FIG. 24) and a data line DL (see FIG. 24). The data line DL may be integrally formed with the first sub-pad SPD1, but the present disclosure is not limited thereto.

The first planarization layer 160 for flattening the stepped portion formed by the active layer ACT, the first gate layer GTL1, the second gate layer GTL2, and the first data metal layer DTL1 may be disposed on the first data metal layer DTL1 and the second interlayer insulating layer 142. The first planarization layer 160 may be formed of an organic layer such as acryl resin, epoxy resin, phenolic resin, polyamide resin, polyimide resin and the like. A first insulating layer 161 may be disposed on the first planarization layer 160.

The second data metal layer DTL2 may be disposed on the first insulating layer 161. The second data metal layer DTL2 may include a second connection electrode CE2. The second connection electrode CE2 may be connected to the first connection electrode CE1 through a second contact hole CT2 penetrating the first insulating layer 161 and the first planarization layer 160. The second data metal layer DTL2 may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof. As will be described later, the second data metal layer DTL2 may further include a second sub-pad SPD2 (see FIG. 24).

In one or more embodiments, the first insulating layer 161 may be formed between the first planarization layer 160 and the second data metal layer DTL2. The first insulating layer 161 may be formed of an inorganic layer, for example, a silicon nitride layer, a silicon oxynitride layer, a silicon oxide layer, a titanium oxide layer, or an aluminum oxide layer. The first insulating layer 161 may be omitted.

The second planarization layer 180 may be disposed on the second data metal layer DTL2 and the first insulating layer 161. The second planarization layer 180 may be formed of an organic layer such as acryl resin, epoxy resin, phenolic resin, polyamide resin, polyimide resin and the like. A second insulating layer 181 may be disposed on the second planarization layer 180.

The third data metal layer DTL3 may be disposed on the second insulating layer 181. The third data metal layer DTL3 may include a third connection electrode CE3. The third connection electrode CE3 may be connected to the second connection electrode CE2 through a third contact hole CT3 penetrating the second insulating layer 181 and the second planarization layer 180. The third data metal layer DTL3 may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof. The third data metal layer DTL3 may further include a third sub-pad SPD3 (see FIG. 24).

In one or more embodiments, the second insulating layer 181 may be formed between the second planarization layer 180 and the third data metal layer DTL3. The second insulating layer 181 may be formed of an inorganic layer, for example, a silicon nitride layer, a silicon oxynitride layer, a silicon oxide layer, a titanium oxide layer, or an aluminum oxide layer. The second insulating layer 181 may be omitted.

The third planarization layer 190 may be disposed on the third data metal layer DTL3 and the second insulating layer 181. The third planarization layer 190 may be formed of an organic layer such as acryl resin, epoxy resin, phenolic resin, polyamide resin, polyimide resin and the like. A third insulating layer 191 may be disposed on the third planarization layer 190.

The fourth data metal layer DTL4 may be disposed on the third insulating layer 191. The fourth data metal layer DTL4 may include the electrode pads, e.g., the first electrode pad APD1, the second electrode pad APD2, the third electrode pad APD3, and the common electrode pad CPD. The first electrode pad APD1 may be connected to the third connection electrode CE3 through a fourth contact hole CT4 penetrating the third insulating layer 191 and the third planarization layer 190. The common electrode pad CPD may receive a first power voltage that is a low potential voltage. The fourth data metal layer DTL4 may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof. The fourth data metal layer DTL4 may further include a fourth sub-pad SPD4 (see FIG. 24).

A transparent conductive layer TCO for increasing an adhesive strength with the first contact electrode CTE1 and the second contact electrode CTE2 of the light emitting elements LE1, LE2, and LE3 may be disposed on the electrode pads. For example, the transparent conductive layer TCO may increase the adhesive strength between the first to third electrode pads APD1, APD2, and APD3 and the first contact electrode CTE1, and between the common electrode pad CPD and the second contact electrode CTE2. The transparent conductive layer TCO may be made of a transparent conductive oxide such as indium tin oxide (ITO) and indium zinc oxide (IZO). A fifth sub-pad SPD5 of FIG. 24 and the transparent conductive layer TCO may be formed at the same layer and may include the same material.

In one or more embodiments, the third insulating layer 191 may be formed between the third planarization layer 190 and the fourth data metal layer DTL4. The third insulating layer 191 may be formed of an inorganic layer, e.g., a silicon nitride layer, a silicon oxynitride layer, a silicon oxide layer, a titanium oxide layer, or an aluminum oxide layer. The third insulating layer 191 may be omitted.

The pixel defining layer PDL may be formed on the third insulating layer 191. The pixel defining layer PDL may be disposed to be around (e.g., to surround) the pixel PX. In one or more embodiments, the pixel defining layer PDL may be disposed for each pixel PX including a plurality of sub-pixels to distinguish them. The pixel defining layer PDL may be disposed to be around (e.g., to surround) the first to third electrode pads APD1, APD2, and APD3 and the common electrode pad CPD forming the pixel PX. The pixel defining layer PDL may be formed of an organic layer such as acryl resin, epoxy resin, phenolic resin, polyamide resin, polyimide resin and the like.

The plurality of protrusions 50 may be formed on the third insulating layer 191. The plurality of protrusions 50 may protrude from the front surface of the substrate 100. The plurality of protrusions 50 may include the first protrusions 51 formed on the electrode pads and the second protrusions 52 formed between the electrode pads.

FIG. 10 illustrates the second protrusions 52 from among the plurality of protrusions 50. The second protrusions 52 may be disposed on the same plane as the pixel defining layer PDL and the electrode pads. The second protrusions 52 may protrude from the top surface of the third insulating layer 191, and may be covered by the first passivation layer PVX1. The second protrusions 52 may be formed between the electrode pads on the third insulating layer 191 in the first direction DR1. For example, the second protrusions 52 may be formed between the first electrode pad APD1 and the common electrode pad CPD, between the second electrode pad APD2 and the common electrode pad CPD, and between the third electrode pad APD3 and the common electrode pad CPD in the first direction DR1.

FIG. 11 illustrates the first protrusions 51 and the second protrusions 52 from among the plurality of protrusions 50. The first protrusions 51 may overlap the electrode pads in the third direction DR3. For example, the first protrusion 51 may protrude from the top surface of the common electrode pad CPD, and may be in contact with the top surface of the transparent conductive layer TCO on the common electrode pad CPD. The first protrusions 51 may not be covered by the first passivation layer PVX1. In one or more embodiments, when the transparent conductive layer TCO is omitted, the first protrusion 51 may be in contact with the top surface of the common electrode pad CPD. In one or more embodiments, the first protrusion 51 may protrude from the top surface of the first electrode pad APD1, and may be in contact with the top surface of the first electrode pad APD1.

The plurality of protrusions 50 and the pixel defining layer PDL may be formed by the same process and may include the same material. The plurality of protrusions 50 may be formed on the same plane as the pixel defining layer PDL. For example, after the third insulating layer 191 is formed, an organic layer is coated on the entire surface thereof and then patterned by a photo-lithography method, thereby forming the pixel defining layer PDL and the plurality of protrusions 50. The plurality of protrusions 50 may include an organic layer such as an acrylic resin, an epoxy resin, a phenolic resin, a polyamide resin, a polyimide resin, or the like.

The plurality of protrusions 50 may be formed to be around (e.g., to surround) the conductive balls 22 of the conductive adhesive member 20. The conductive balls 22 may be formed between the plurality of protrusions 50. For example, some of the conductive balls 22 may be formed between the first protrusion 51 and the second protrusion 52. Because the protrusions 50 are formed to be around (e.g., to surround) the conductive balls 22, the protrusions 50 may prevent the conductive balls 22 from being moved by the fluidity of the adhesive resin 21.

The first passivation layer PVX1 may be disposed on the first electrode pad APD1, the common electrode pad CPD, the pixel defining layer PDL, and the plurality of protrusions 50. The first passivation layer PVX1 may be disposed to cover the edges of the first electrode pad APD1 and the common electrode pad CPD. The first passivation layer PVX1 may be disposed to completely cover the pixel defining layer PDL. The first passivation layer PVX1 may be disposed to cover the second protrusion 52 without covering the first protrusion 51. The first passivation layer PVX1 may be formed of an inorganic layer, for example, a silicon nitride layer, a silicon oxynitride layer, a silicon oxide layer, a titanium oxide layer, or an aluminum oxide layer.

The first light emitting element LE1 may be disposed on the first electrode pad APD1 and the common electrode pad CPD that are not covered by the first passivation layer PVX1. A case where the first light emitting element LE1 is a flip chip type micro LED in which the first contact electrode CTE1 opposes the first electrode pad APD1 and the second contact electrode CTE2 opposes the common electrode pad CPD was illustrated. The first light emitting element LE1 may contain an inorganic material such as GaN. The length of the first light emitting element LE1 in the horizontal direction (i.e., the first direction DR1 or the second direction DR2) and the length thereof in the third direction DR3 may be several to several hundreds of μm.

The first light emitting element LE1 may be formed by growing on a semiconductor substrate such as a silicon wafer. The first light emitting element LE1 may be directly transferred from the silicon wafer onto the first electrode pad APD1 and the common electrode pad CPD of the substrate 100. Alternatively, the first light emitting element LE1 may be transferred onto the first electrode pad APD1 and the common electrode pad CPD of the substrate 100 by an electrostatic method using an electrostatic head or a stamping method using an elastic polymer material such as PDMS or silicon as a transfer substrate.

The first light emitting element LE1 may be a light emitting structure including a base substrate PSUB, an n-type semiconductor NSEM, an active layer MQW, a p-type semiconductor PSEM, a first contact electrode CTE1, and a second contact electrode CTE2.

The base substrate PSUB may be a sapphire substrate, but the present disclosure is not limited thereto.

The n-type semiconductor NSEM may be disposed on one surface of the base substrate PSUB. For example, the n-type semiconductor NSEM may be disposed on the bottom surface of the base substrate PSUB. The n-type semiconductor NSEM may be formed of GaN doped with an n-type conductive dopant such as Si, Ge, Sn or Se.

The active layer MQW may be disposed on a part of one surface of the n-type semiconductor NSEM. The active layer MQW may emit light by coupling of electron-hole pairs according to an electrical signal through an electron of the n-type semiconductor NSEM and a hole of the p-type semiconductor PSEM. The active layer MQW may include a material having a single or multiple quantum well structure. When the active layer MQW contains a material having a multiple quantum well structure, the active layer MQW may have the structure in which a plurality of well layers and barrier layers are alternately laminated. At this time, the well layer may be formed of InGaN, and the barrier layer may be formed of GaN or AlGaN, but the present disclosure is not limited thereto. Alternatively, the active layer MQW may have a structure in which semiconductor materials having large band gap energy and semiconductor materials having small band gap energy are alternately stacked, and may include other Group III to V semiconductor materials according to the wavelength band of the emitted light.

The p-type semiconductor PSEM may be disposed on one surface of the active layer MQW. The p-type semiconductor PSEM may be formed of GaN doped with a p-type conductive dopant such as Mg, Zn, Ca, or Ba.

The first contact electrode CTE1 may be disposed on the p-type semiconductor PSEM, and the second contact electrode CTE2 may be disposed on another part of one surface of the n-type semiconductor NSEM. The another part of one surface of the n-type semiconductor NSEM on which the second contact electrode CTE2 is disposed may be spaced from the part of one surface of the n-type semiconductor NSEM on which the active layer MQW is disposed.

The first contact electrode CTE1 and the first electrode pad APD1 may be bonded to each other by the conductive adhesive member 20. Alternatively, the first contact electrode CTE1 and the first electrode pad APD1 may be bonded to each other by a soldering process.

The second contact electrode CTE2 and the common electrode pad CPD may be bonded to each other by the conductive adhesive member 20. Alternatively, the second contact electrode CTE2 and the common pad electrode CPD may be bonded to each other by the soldering process.

The conductive adhesive member 20 may be formed between the first passivation layer PVX1 and the light emitting elements LE1, LE2, and LE3, and may be formed between the electrode pads and the light emitting elements LE1, LE2, and LE3. The adhesive resin 21 of the conductive adhesive member 20 may be coated on the entire top surface of the substrate 100, and the conductive balls 22 may be non-uniformly dispersed in the adhesive resin 21. The conductive adhesive member 20 may electrically connect the first light emitting element LE1, the second light emitting element LE2, and the third light emitting element LE3 to the electrode pads of the thin film transistor layer TFTL, and may fix them.

The first to third electrode pads APD1, APD2, and APD3 and the common electrode pad CPD may be electrically connected to the plurality of light emitting elements LE1, LE2, and LE3 by the conductive balls 22. The conductive balls 22 may be conductive particles electrically connecting the plurality of light emitting elements LE1, LE2, and LE3 and the electrode pads. For example, the conductive balls 22 may be positioned between the first contact electrode CTE1 and the first electrode pad APD1 and overlap them in the third direction DR3. The conductive balls 22 may be in contact via the transparent conductive layer (TCO) with the first electrode pad APD1 and the first contact electrode CTE1. The conductive balls 22 may be positioned between the second contact electrode CTE2 and the common electrode pad CPD and overlap them in the third direction DR3. The conductive balls 22 may be in contact via the transparent conductive layer (TCO) with the common electrode pad CPD and the second contact electrode CTE2.

Some others of the plurality of conductive balls 22 may not overlap the light emitting elements LE1, LE2, and LE3 in the third direction DR3. The conductive balls 22 may be disposed around the light emitting elements LE1, LE2, and LE3. In this case, the conductive ball 22 does not serve as an electrical medium, so that the display device 10 may have an insulating property in the first direction DR1 and the second direction DR2.

In accordance with one or more embodiments, the plurality of protrusions 50 protruding from the front surface of the substrate 100 may prevent the conductive balls 22 connecting the contact electrodes CTE1 and CTE2 and the electrode pads from being moved out of the electrode pads. Because the conductive ball 22 is fixed by the plurality of protrusions 50, poor connection between the light emitting elements LE1, LE2, and LE3 and the electrode pads may be suppressed. For example, from among the plurality of protrusions 50, the first protrusions 51 may be formed on the first to third electrode pads APD1, APD2, and APD3 and the common electrode pad CPD. Among the plurality of protrusions 50, the second protrusions 52 may be formed between the first electrode pad APD1 and the common electrode pad CPD, between the second electrode pad APD2 and the common electrode pad CPD, and between the third electrode pad APD3 and the common electrode pad CPD. The plurality of protrusions 50 may prevent the plurality of conductive balls 22 from being moved out of the first to third electrode pads APD1, APD2, and APD3 and the common electrode pad CPD. The display device 10 in which occurrence of dark spots or electrical short circuit is suppressed may be formed.

In one or more embodiments, from among the plurality of conductive balls 22, the conductive balls 22 positioned between the electrode pads and the contact electrodes CTE1 and CTE2 may be deformed during a manufacturing process and may not have a spherical shape. For example, one surfaces of the conductive balls 22 that are in contact with the electrode pads and the contact electrodes CTE1 and CTE2 may be deformed into a flat shape. In FIG. 11, in the conductive ball 22 positioned between the first contact electrode CTE1 and the first electrode pad APD1, one surface in contact with the first contact electrode CTE1 and the other surface in contact with the first electrode pad APD1 may deformed into a flat shape. Further, in the conductive ball 22 positioned between the second contact electrode CTE2 and the common electrode pad CPD, one surface in contact with the second contact electrode CTE2 and the other surface in contact with the common electrode pad CPD may be deformed into a flat shape.

In one or more embodiments, a thickness TH1 of the first contact electrode CTE1 and a thickness TH2 of the second contact electrode CTE2 may be different. The thickness TH1 of the first contact electrode CTE1 may be less than the thickness TH2 of the second contact electrode CTE2. The height of the bottom surface where the first contact electrode CTE1 meets the conductive ball 22 and the height of the bottom surface where the second contact electrode CTE2 meets the conductive ball 22 may be formed uniformly. For example, the difference between the height of the bottom surface of the first contact electrode CTE1 and the height of the bottom surface of the second contact electrode CTE2 may be about 1 μm or less.

Accordingly, a first contact area where the first contact electrode CTE1 is in contact with the conductive ball 22 and a second contact area where the second contact electrode CTE2 is in contact with the conductive ball 22 may be uniform. Further, a third contact area where the first electrode pad APD1 is in contact with the conductive ball 22 and a fourth contact area where the common electrode pad CPD is in contact with the conductive ball 22 may be uniform. As the contact area becomes more uniform, a contact resistance difference may be reduced or minimized. Because the contact resistance difference is reduced or minimized, it may be possible to prevent a decrease in the injection efficiency of the current applied to the first light emitting element LE1. Accordingly, the image quality of the display device 10 may be improved. For example, it is possible to suppress the generation of a stain such as Mura, or improve the grayscale characteristics or Gamut characteristics.

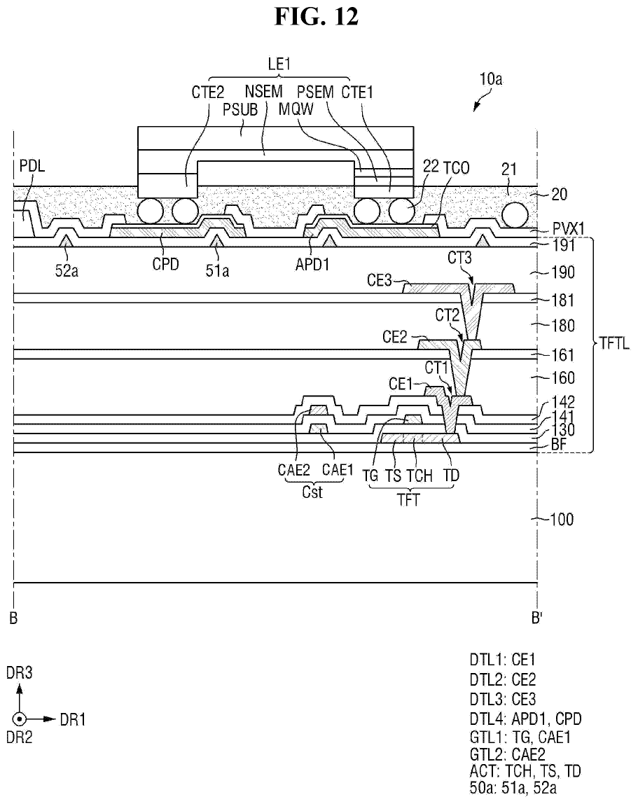

FIG. 12 is an example of a cross-sectional view taken along the line B-B′ of FIG. 7.

The embodiment of FIG. 12 is different from the embodiment of FIG. 11 in that a plurality of protrusions 50a (51a and 52a) and the third planarization layer 190 are formed by the same process and include the same material. Specifically, the embodiment of FIG. 11 is different from the embodiment of FIG. 12 in that the plurality of protrusions 50 and the pixel defining layer PDL are formed by the same process and include the same material. The embodiment of FIG. 12 is the same as the embodiment of FIG. 11 in that the plurality of protrusions 50a include the first protrusion 51a formed to overlap the first electrode pad APD1 and the common electrode pad CPD and the second protrusion 52a formed between the first electrode pad APD1 and the common electrode pad CPD.

Hereinafter, differences from the previous embodiment will be mainly described, and redundant description will be omitted.

The plurality of protrusions 50a may protrude from the top surface of the third planarization layer 190. The plurality of protrusions 50a may be completely covered by the third insulating layer 191. Because the plurality of protrusions 50a are made of the same material as that of the third planarization layer 190, they may contain an organic insulating material. Among the plurality of protrusions 50a, the first protrusions 51a may be disposed under the electrode pads. For example, the first protrusions 51a may be disposed under the first electrode pad APD1 and the common electrode pad CPD. Further, the plurality of first protrusions 51a and second protrusions 52a may be disposed under the third insulating layer 191 and the first passivation layer PVX1.

The third insulating layer 191 may be disposed on the third planarization layer 190 and the plurality of protrusions 50a. The third insulating layer 191 may completely cover the plurality of protrusions 50a.

The electrode pads may be disposed on the third insulating layer 191. The electrode pads may be disposed on some of the protrusions 50a from among the plurality of protrusions 50a. The electrode pads may have a stepped portion depending on the shape of the protrusion 50a. For example, the first electrode pad APD1 and the common electrode pad CPD may be disposed on the plurality of first protrusions 51a, and the first electrode pad APD1 and the common electrode pad CPD may have a stepped portion depending on the shape of the first protrusions 51a. The first electrode pad APD1 and the common electrode pad CPD may have top surfaces where a first area overlapping the first protrusions 51a is higher than a second area not overlapping the first protrusions 51a.

The first passivation layer PVX1 covering the top surfaces of the pixel defining layer PDL, the third insulating layer 191, the first electrode pad APD1, and the common electrode pad CPD may be further disposed. The first passivation layer PVX1 may be formed along the stepped portions of the first electrode pad APD1 and the common electrode pad CPD.

In accordance with one or more embodiments, the plurality of protrusions 50a are disposed to be around (e.g., to surround) the plurality of conductive balls 22 in a plan view while protruding from the third planarization layer 190, so that the plurality of conductive balls 22 may not be moved out of the electrode pads. Because the plurality of conductive balls 22 are fixed by the plurality of protrusions 50a, poor connection between the first light emitting element LE1 and the electrode pads may be suppressed. Accordingly, due to the plurality of conductive balls 22, the first electrode pad APD1 and the first contact electrode CTE1 may be connected, and the common electrode pad CPD and the second contact electrode CTE2 may be connected. The occurrence of dark spots or electrical short circuit of the display device 10a may be suppressed.

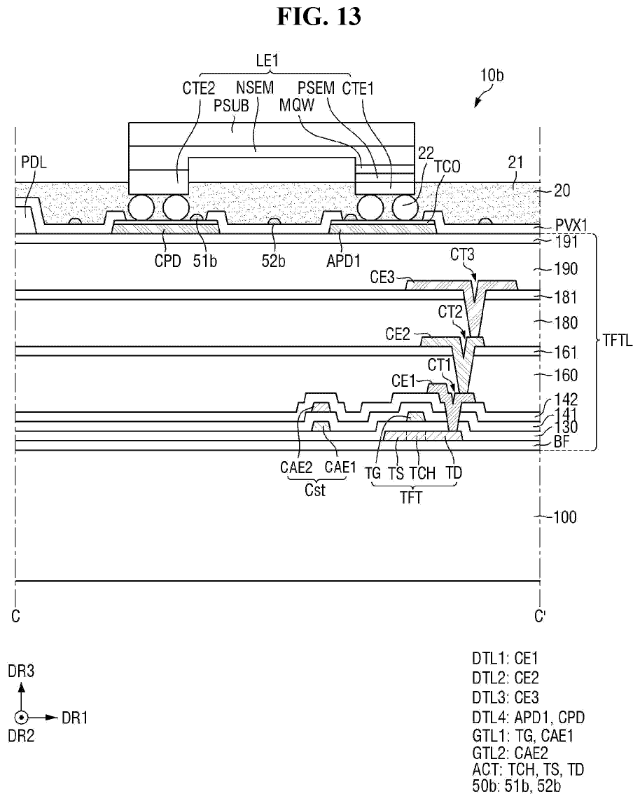

FIG. 13 is an example of a cross-sectional view taken along the line C-C′ of FIG. 8.

The embodiment of FIG. 13 is different from the embodiment of FIGS. 7 and 8 in that the plurality of protrusions 50b and the first passivation layer PVX1 are formed by the same process and include the same material. Further, the plurality of protrusions 50b having a hemispherical structure are illustrated. The embodiment of FIG. 13 is the same as the embodiment of FIGS. 7 and 8 in that the plurality of protrusions 50b include first protrusions 51b overlapping the first electrode pad APD1 and the common electrode pad CPD, and second protrusions 52b formed between the first electrode pad APD1 and the common electrode pad CPD.

Hereinafter, differences from the previous embodiment will be mainly described, and redundant description will be omitted.

The plurality of protrusions 50b may protrude from the top surface of the first passivation layer PVX1. Because the plurality of protrusions 50b are made of the same material as the first passivation layer PVX1, they may contain an inorganic insulating material. The plurality of protrusions 50b may be formed on the top surfaces of the electrode pads, or may be formed on the top surface of the first passivation layer PVX1. For example, the first protrusions 51b may be formed on the top surface of the first electrode pad APD1 or the common electrode pad CPD (e.g., the first protrusions 51b may be formed on the top surface of the transparent conductive layer (TCO) on the first electrode pad APD1 or the common electrode pad CPD), and the second protrusions 52b may be formed on the top surface of the first passivation layer PVX1 between the first electrode pad APD1 and the common electrode pad CPD.

In accordance with one or more embodiments, the plurality of protrusions 50b are disposed to be around (e.g., to surround) the plurality of conductive balls 22 in a plan view while protruding from the first passivation layer PVX1, so that the plurality of conductive balls 22 may not be moved out of the electrode pads. Because the plurality of conductive balls 22 are fixed by the plurality of protrusions 50b, poor connection between the first light emitting element LE1 and the electrode pads may be suppressed. Accordingly, due to the plurality of conductive balls 22, the first electrode pad APD1 and the first contact electrode CTE1 may be connected, and the common electrode pad CPD and the second contact electrode CTE2 may be connected. The occurrence of dark spots or electrical short circuit of the display device 10b may be suppressed.

Hereinafter, other embodiments of the display device for fixing the plurality of conductive balls 22 will be described.

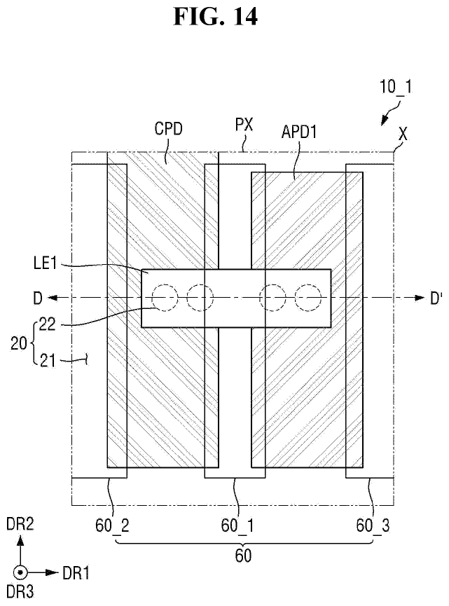

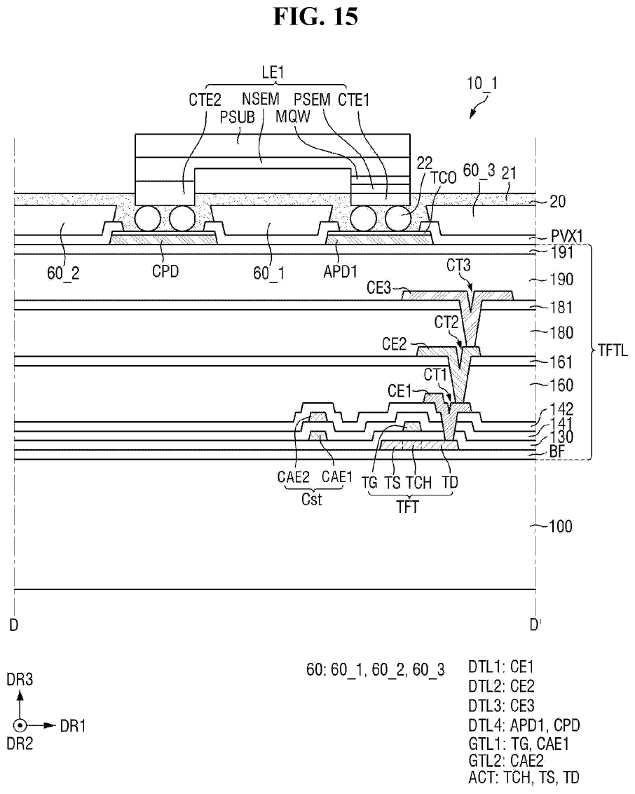

FIG. 14 is an enlarged plan view of a pixel of a display device according to one or more embodiments. FIG. 15 is an example of a cross-sectional view taken along the line D-D′ of FIG. 14.

Referring to FIGS. 14 and 15, in a display device 10_1 according to the present embodiment, dielectric layers 60 (60_1, 60_2, and 60_3) may be formed to fix or trap the plurality of conductive balls 22. Because the dielectric layer 60 may trap the plurality of conductive balls 22, the density of the conductive balls 22 between the first light emitting element LE1 and the electrode pads APD1 and CPD may be increased. Accordingly, the contact area between the first light emitting element LE1 and the electrode pads APD1 and CPD may be increased.

The dielectric layer 60 may include a first dielectric layer 60_1 formed between the first electrode pad APD1 and the common electrode pad CPD, a second dielectric layer 60_2 formed on one side of the common electrode pad CPD, and a third dielectric layer 60_3 formed on one side of the first electrode pad APD1. The first dielectric layer 60_1 may be formed between the second dielectric layer 60_2 and the third dielectric layer 60_3.

The dielectric layer 60 may be formed on the first passivation layer PVX1, and may have an inclined reverse taper shape or a reverse-mesa shape in which the length decreases from the top surface toward the bottom surface. The dielectric layer 60 may be formed between the pad electrodes APD1 and CPD to prevent the plurality of conductive balls 22 from being moved out of the electrode pads APD1 and CPD.

The dielectric layer 60 may be made of an organic material. In this case, the dielectric layer 60 may be formed by a photolithography method.

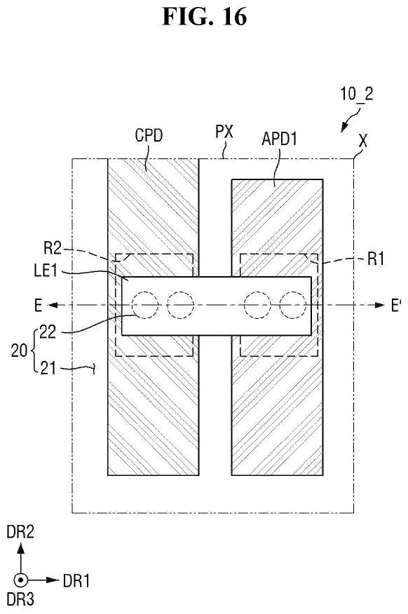

Hereinafter, a display device 10_2 according to one or more embodiments will be described with reference to FIGS. 16 to 18.

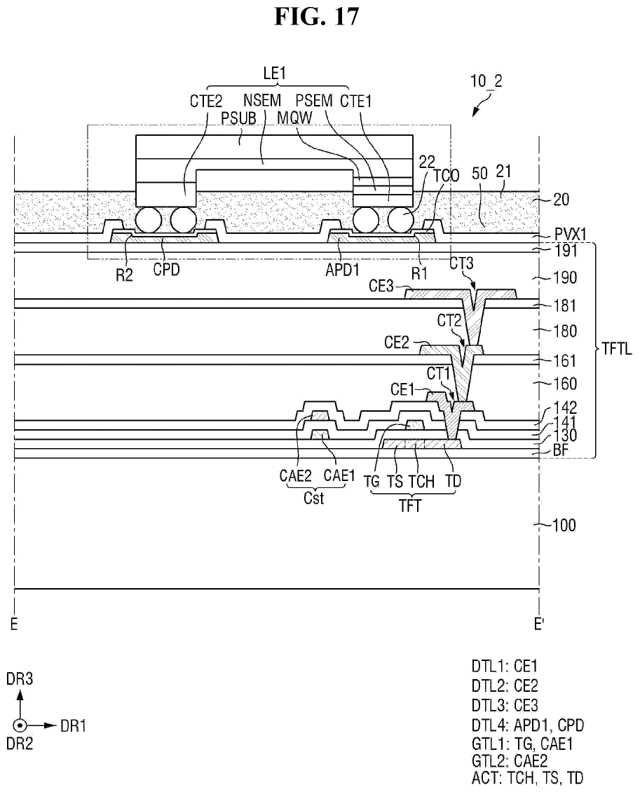

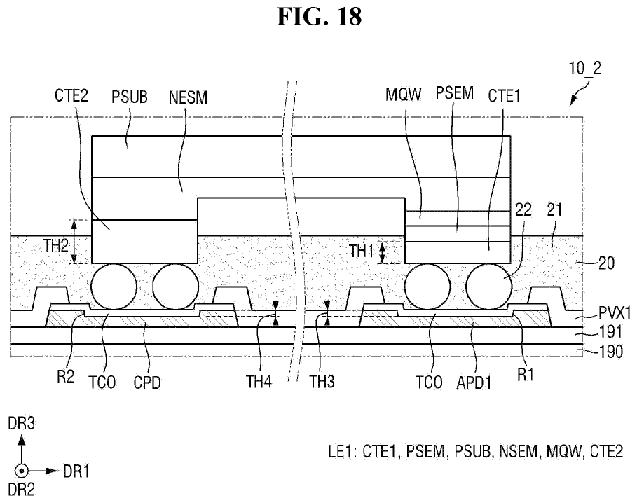

FIG. 16 is an enlarged plan view of a pixel of a display device according to one or more embodiments. FIG. 17 is an example of a cross-sectional view taken along the line E-E′ of FIG. 16. FIG. 18 is an enlarged cross-sectional view of a pad metal layer and a light emitting element of FIG. 17.

In the display device 10_2 according to the present embodiment, the plurality of conductive balls 22 may be fixed by forming a plurality of recesses R1 and R2 in the electrode pads APD1 and CPD. Because the plurality of conductive balls 22 may be fixed in the plurality of recesses R1 and R2 formed in the electrode pads APD1 and CPD, it is possible to prevent the plurality of conductive balls 22 from being moved out of the electrode pads APD1 and CPD by the fluidity of the conductive adhesive member 20.

For example, the first electrode pad APD1 may have a first recess R1 recessed from the top surface of the first electrode pad APD1. The first recess R1 may be recessed from the top surface of the first electrode pad APD1 while partially penetrating the first electrode pad APD1. The side surfaces and top surface of the first electrode pad APD1 may be exposed by the first recess R1.

For another example, the common electrode pad CPD may have a second recess portion R2 recessed from the top surface of the common electrode pad CPD. The second recess R2 may be recessed from the top surface of the common electrode pad CPD while partially penetrating the common electrode pad CPD. The side surfaces and top surface of the common electrode pad CPD may be exposed by the second recess R2.

The recesses R1 and R2 of the electrode pads APD1 and CPD may be formed by dry etching or wet etching, but the present disclosure is not limited thereto.

In FIG. 16, the first recess R1 and the second recess R2 may be formed in the first electrode pad APD1 and the common electrode pad CPD, respectively. Although the first recess R1 and the second recess R2 having a rectangular shape are illustrated, the present disclosure is not limited thereto. For example, the first recess R1 and the second recess R2 may have a polygonal shape such as a square shape and a rhombus shape, a circular shape, an elliptical shape, or the like.

The conductive balls 22 connected to the first contact electrode CTE1 may be disposed in the first recess R1. The conductive balls 22 may be fixed in the first recess R1, and may not be moved out of the first electrode pad APD1 due to the protrusions at both ends of the first electrode pad APD1. In this case, the thickness of the first electrode pad APD1 may be about 3 μm or more, and a recessed thickness TH3 of the first recess R1 may be about 1 μm or more. In other words, the recessed thickness TH3 of the first recess R1 may be at least ⅓ of the thickness of the first electrode pad APD1.

The conductive balls 22 connected to the second contact electrode CTE2 may be disposed in the second recess R2. The conductive balls 22 may be fixed in the second recess R2, and may not be moved out of the common electrode pad CPD due to the protrusions at both ends of the common electrode pad CPD. In this case, the thickness of the common electrode pad CPD may be about 3 μm or more, and a recessed thickness TH4 of the second recess R2 may be about 1 μm or more. In other words, the recessed thickness TH4 of the second recess R2 may be at least ⅓ of the thickness of the common electrode pad CPD.

On the other hand, the radius of the conductive balls 22 fixed in the first recess R1 and the second recess R2 may be greater than the recessed thickness TH3 of the first recess R1 and the recessed thickness TH4 of the second recess R2. For example, the radius of the conductive ball 22 may be 1.5 μm to 2.5 μm. The center of the conductive ball 22 formed in the first recess R1 may be located higher than the top surface of the first electrode pad APD1, and the conductive ball 22 may be in contact with the first contact electrode CTE1. The center of the conductive ball 22 formed in the second recess R2 may be located higher than the top surface of the common electrode pad CPD, and the conductive ball 22 may be in contact with the second contact electrode CTE2.

The first contact electrode CTE1 of the first light emitting element LE1 may overlap the first recess R1, and the second contact electrode CTE2 may overlap the second recess R2.

Further, the thickness TH1 of the first contact electrode CTE1 may be smaller than the thickness TH2 of the second contact electrode CTE2. Accordingly, the contact position between the first contact electrode CTE1 and the conductive ball 22 and the contact position between the second contact electrode CTE2 and the conductive ball 22 may be substantially the same, or may have an error of 1 μm or less.

In the display device 10_2 according to the present embodiment, the plurality of conductive balls 22 may be fixed by forming the plurality of recesses R1 and R2 in the electrode pads APD1 and CPD, so that the density of the conductive balls 22 connecting the first light emitting element LE1 and the electrode pads APD1 and CPD may be increased, and the distribution density of the conductive balls 22 may become uniform. Accordingly, it is possible to suppress occurrence of dark spots and electrical short circuit due to poor connection between the first light emitting element LE1 and the electrode pads APD1 and CPD. Further, the contact area between the first light emitting element LE1 and the electrode pads APD1 and CPD may be increased by the conductive ball 22.

To implement a super-large/ultra-high-resolution micro LED display device, it is necessary to reduce the gap between the electrode pads APD1 and CPD of the thin film transistor layer TFTL, and also necessary to reduce the chip size of the micro LED.

In the display device 10_2 according to the present embodiment, the plurality of recesses R1 and R2 are formed in the electrode pads APD1 and CPD, so that the conductive ball 22 may be fixed in the recesses R1 and R2. Therefore, even if the gap between the electrode pads APD1 and CPD is reduced, the conductive ball 22 may not be moved out of the electrode pads APD1 and CPD. In other words, even if the gap between the electrode pads APD1 and CPD is reduced to implement the super-large/ultra-high-resolution display device 10_2, poor connection of the display device 10_2 may not occur.

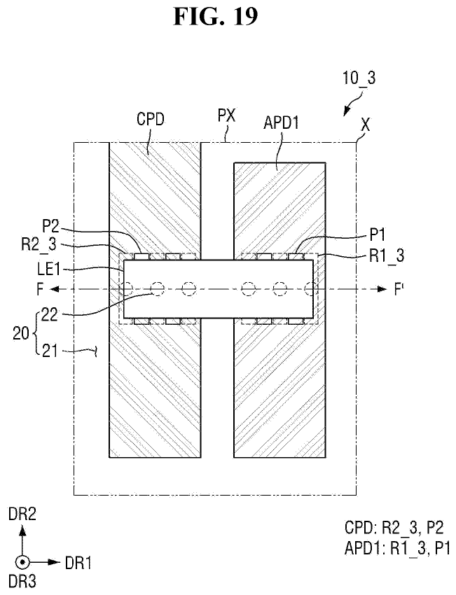

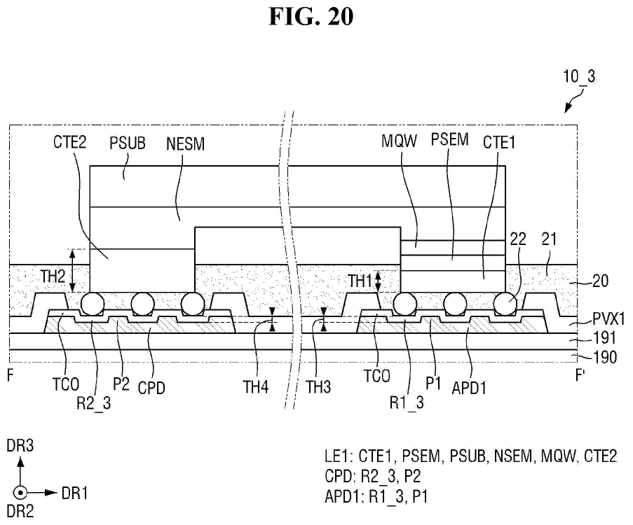

Hereinafter, a display device 10_3 according to one or more embodiments will be described with reference to FIGS. 19 and 20.

FIG. 19 is an enlarged plan view of a pixel of a display device according to one or more embodiments. FIG. 20 is a cross-sectional view illustrating a pad metal layer and a light emitting element taken along the line F-F′ of FIG. 19.

Referring to FIGS. 19 and 20, in the display device 10_2 according to the present embodiment, the electrode pads APD1 and CPD may be formed in an embossing structure in order to more stably fix the plurality of conductive balls 22 in the electrode pads APD1 and CPD and improve the reliability of the display device 10_2. For example, the electrode pads APD1 and CPD may have an uneven structure in which at least some of them are recessed and at least some others of them protrude.

Specifically, the present embodiment is different from the previous embodiment in that the first electrode pad APD1 includes first recesses R1_3 and first protrusions P1, and the common electrode pad CPD includes second recesses R2_3 and second protrusions P2. Hereinafter, differences from the previous embodiment will be mainly described, and redundant description will be omitted.

The first electrode pad APD1 may include the first recesses R1_3 and the first protrusions P1. The first recesses R1_3 and the first protrusions P1 may be repeatedly arranged along one direction. The one direction may be the same as the first direction DR1 in which the first light emitting element LE1 extends, but is not limited thereto. The first recesses R1_3 may be recessed from the top surface of the first electrode pad APD1 while partially penetrating the first electrode pad APD1. The side surfaces and top surface of the first electrode pad APD1 may be exposed by the first recess R1_3. The first protrusions P1 may be formed between the first recesses R1_3, and may protrude from the top surface of the first recess R1_3. The top surface of the first protrusion P1 may be positioned on the same plane as the unexposed top surface of the first electrode pad APD1. In the first electrode pad APD1, the thickness of the first recess R1_3 may be smaller than the thickness of the first protrusion P1.

The common electrode pad CPD may include the second recesses R2_3 and the second protrusions P2. The second recesses R2_3 and the second protrusions P2 may be repeatedly arranged along one direction. The one direction may be the same as the first direction DR1 in which the first light emitting element LE1 extends, but is not limited thereto. The second recesses R2_3 may be recessed from the top surface of the common electrode pad CPD while partially penetrating the common electrode pad CPD. The side surfaces and top surface of the common electrode pad CPD may be exposed by the second recess R2_3. The second protrusions P2 may be formed between the second recesses R2_3, and may protrude from the top surface of the second recess R2_3. The top surface of the second protrusion P2 may be disposed on the same plane as the unexposed top surface of the common electrode pad CPD. In the common electrode pad CPD, the thickness of the second recess R2_3 may be smaller than the thickness of the second protrusion P2.

Although one first electrode pad APD1 having three first recesses R1_3 and two first protrusions P1 is illustrated in the drawing, the present disclosure is not limited thereto. The length of the first recess R1_3 in the first direction DR1 may be long enough to fix the conductive balls 22. Further, although one common electrode pad CPD having three second recesses R2_3 and two second protrusions P2 is illustrated, the present disclosure is not limited thereto. The length of the second recess R2_3 in the first direction DR1 may be long enough to fix the conductive balls 22. In one or more embodiments, the lengths of the first electrode pad APD1 and the common electrode pad CPD in the first direction DR1 may be about 10 μm, and the lengths thereof in the second direction DR2 may be about 15 μm. In this case, the lengths of the first recess R1_3, the second recess R2_3, the first protrusion P1, and the second protrusion P2 in the first direction DR1 may be 2 μm or less.

The first contact electrode CTE1 of the first light emitting element LE1 may overlap the first recess R1_3 and the first protrusion P1, and the second contact electrode CTE2 may overlap the second recess R2_3 and the second protrusion P2.

In the display device 10_3 according to the present embodiment, the plurality of recesses R1_3 and R2_3 and the plurality of protrusions P1 and P2 are formed in the electrode pads APD1 and CPD, so that the plurality of conductive balls 22 may be fixed. Because the first light emitting element LE1 and the electrode pads APD1 and CPD may be stably connected by the fixed conductive balls 22, the reliability of the display device 10_3 may be improved.

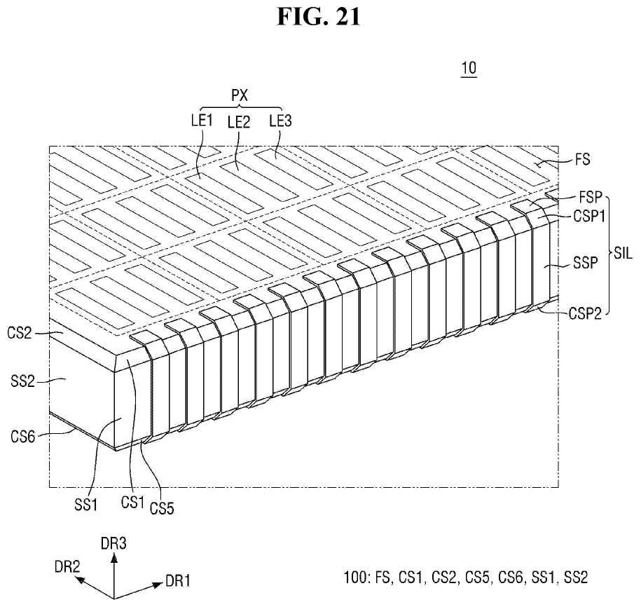

FIG. 21 is a perspective view illustrating in detail one edge of a display device according to one or more embodiments. FIG. 22 is a plan view illustrating an arrangement relationship between a pixel and a side line of a display device according to one or more embodiments. FIG. 23 is a rear view illustrating an arrangement relationship between a pixel and a side line of a display device according to one or more embodiments.

Referring to FIGS. 21 to 23, the display device 10 includes the first pads PD1, the second pads PD2, the third pads PD3, and rear surface connection lines BCL.

The first pads PD1 may be front surface pads disposed on the first surface FS corresponding to the front surface of the substrate 100. The first pads PD1 may be disposed at a first edge of the first surface FS of the substrate 100. The first pads PD1 may be arranged along the first direction DR1.

The second pads PD2 may be rear surface pads disposed on the second surface BS corresponding to the rear surface of the substrate 100. The second pads PD2 may be disposed at a first edge of the second surface BS of the substrate 100. The second pads PD2 may be arranged along the first direction DR1.

The third pads PD3 may be rear surface pads disposed on the second surface BS of the substrate 100. The third pads PD3 may be disposed closer to the center of the second surface BS of the substrate 100 compared to the second pads PD2. The third pads PD3 may be arranged along the first direction DR1. In order to connect a larger number of third pads PD3 to the circuit board 200, the gap between the third pads PD3 adjacent to each other in the first direction DR1 may be smaller than the gap between the second pads PD2 adjacent to each other in the first direction DR1.

The rear surface connection line BCL serves to connect the second pad PD2 and the third pad PD3. Because the gap between the second pads PD2 adjacent to each other in the first direction DR1 and the gap between the third pads PD3 adjacent to each other in the first direction DR1 are different, the rear surface connection line BCL may be bent at least once. The rear surface connection line BCL may be integrally formed with the second pad PD2 and the third pad PD3. The second pad PD2, the third pad PD3, and the rear surface connection line BCL may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

The side line SIL may include first to fifth portions FSP, CSP1, SSP, CSP2, and BSP.

The first portion FSP corresponds to a front surface portion disposed on the first surface FS of the substrate 100. The first portion FSP may be disposed on the first pad PD1, and may be disposed to completely cover the first pad PD1. The first portion FSP may be connected to the first pad PD1.

The second portion CSP1 corresponds to a first chamfered portion disposed on the first chamfered surface CS1 of the substrate 100. The second portion CSP1 may be disposed between the first portion FSP and the third portion SSP.

The third portion SSP corresponds to a side surface portion disposed on the first side surface SS1 of the substrate 100. The third portion SSP may be disposed between the second portion CSP1 and the fourth portion CSP2.

The fourth portion CSP2 corresponds to a second chamfered portion disposed on the fifth chamfered surface CS5 of the substrate 100. The fourth portion CSP2 may be disposed between the third portion SSP and the fifth portion BSP.

The fifth portion BSP corresponds to a rear surface portion disposed on the second side surface BS of the substrate 100. The fifth portion BSP may be disposed on the second pad PD2, and may be disposed to completely cover the second pad PD2. The fifth portion BSP may be connected to the second pad PD2.

The side line SIL may include a metal powder containing metal particles such as silver (Ag) and copper (Cu) and a polymer such as an acrylic resin or an epoxy resin. The metal powder may allow the side line SIL to have conductivity, and the polymer may serve as a binder connecting the metal particles.

Specifically, the side line SIL may be formed by printing a metal paste containing metal particles, a monomer, and a solvent on the substrate 100 using a silicon pad and then performing sintering using a laser. The metal particles are in close contact with each other and aggregated as the monomer reacts with the polymer by the heat generated by the laser in the sintering process, so that the specific resistance of the side line 200 may be lowered.

FIG. 24 is a cross-sectional view taken along the line G-G′ of FIG. 23. In FIG. 24, redundant description of parts already described in the embodiment of FIGS. 10 and 11 will be omitted.

FIG. 24 shows the first pad PD1 disposed on the upper side of the display device 10, and the first light emitting element LE1 and the second light emitting element LE2 of the pixel PX. Further, the second pad PD2 and the third pad PD3 disposed on the lower side of the display device 10 are shown.

The first pads PD1 may be disposed at the upper edge of the display device 10. When the data lines DL of the display device 10 extend in the second direction DR2, the first pads PD1 may be disposed at the upper and lower edges of the display device 10. Alternatively, when the data lines DL of the display device 10 extend in the first direction DR1, the first pads PD1 may be disposed at the left and right edges of the display device 10. Although the case where the first pad PD1 is substantially the same as the data line DL for applying a signal for driving the pixel PX was illustrated, the present disclosure is not limited thereto. For example, the first pad PD1 may be substantially the same as another line for applying a signal to the pixel PX.

Each of the first pads PD1 may be connected to the data line DL. Further, each of the first pads PD1 may be connected to the side line SIL. The side line SIL may be disposed on one side surface and the bottom surface (or rear surface) of the substrate 100. The side line SIL may be connected to the rear surface connection line BCL on the bottom surface of the substrate 100 (e.g., via the second pad PD2).

The first pads PD1 may be disposed on the second interlayer insulating layer 142. The first pads PD1 may be exposed without being covered by the first planarization layer 160, the second planarization layer 180, and the third planarization layer 190.

The first pad PD1 may include first to fifth sub-pads SPD1, SPD2, SPD3, SPD4, and SPD5. The first sub-pad SPD1 may be disposed on the second interlayer insulating layer 142, the second sub-pad SPD2 may be disposed on the first sub-pad SPD1, and the third sub-pad SPD3 may be disposed on the second sub-pad SPD2. The fourth sub-pad SPD4 may be disposed on the third sub-pad SPD3, and the fifth sub-pad SPD5 may be disposed on the fourth sub-pad SPD4. Although the case where the first sub-pad SPD1 is included in the first data metal layer DTL1 (see FIG. 10), the second sub-pad SPD2 is included in the second data metal layer DTL2 (see FIG. 10), the third sub-pad SPD3 is included in the third data metal layer DTL3 (see FIG. 10), the fourth sub-pad SPD4 is included in the fourth data metal layer DTL4 (see FIG. 10), and the fifth sub-pad SPD5 is included in a pad electrode layer containing a transparent metal material TCO was illustrated, the present disclosure is not limited thereto.

The rear surface connection line BCL may be disposed on the bottom surface of the substrate 100. The rear surface connection line BCL may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

The second pad PD2 may be disposed at one end of the rear surface connection line BCL, and the third pad PD3 may be disposed at the other end of the rear surface connection line BCL. The second pad PD2 and the third pad PD3 may be made of a transparent conductive oxide such as indium tin oxide (ITO) and indium zinc oxide (IZO).

The fourth planarization layer 170 may be disposed on the rear surface connection line BCL and the rear surface of the substrate 100. The fourth planarization layer 170 may be formed of an organic layer such as acryl resin, epoxy resin, phenolic resin, polyamide resin, polyimide resin and the like.

The second passivation layer PVX2 may be disposed on the fourth planarization layer 170. The second passivation layer PVX2 may be formed of an inorganic layer, for example, a silicon nitride layer, a silicon oxynitride layer, a silicon oxide layer, a titanium oxide layer, or an aluminum oxide layer.

The side line SIL may be disposed on the first surface FS, the second surface BS, the first side surface SS1, the first chamfered surface CS1, and the fifth chamfered surface CS5 of the substrate 100. The side line SIL may be disposed on the first pad PD1 disposed at the edge of the first surface FS of the substrate 100 to be connected to the first pad PD1. The side line SIL may be disposed on the second pad PD2 disposed at the edge of the second surface BS of the substrate 100 to be connected to the second pad PD2. The side line SIL may be in contact with the first chamfered surface CS1, the first side surface SS1, and the fifth chamfered surface CS5 of the substrate 100.

The overcoat layer OC may be disposed on the first surface FS, the first chamfered surface CS1, the first side surface SS1, the fifth chamfered surface CS5, and the second surface BS of the substrate 100. The overcoat layer OC may be disposed to cover the side line SIL. The overcoat layer OC may be formed of an organic layer such as acryl resin, epoxy resin, phenolic resin, polyamide resin, polyimide resin and the like.

The circuit board 200 may be disposed on the rear surface of the substrate 100. The circuit board 200 may be connected to the third pad PD3 that is exposed without being covered by the fourth planarization layer 170 and the second passivation layer PVX2 using the conductive adhesive member CAM. The circuit board 200 may be connected to the third pad PD3 by the conductive adhesive member CAM. The conductive adhesive member CAM may be an anisotropic conductive film or an anisotropic conductive paste.

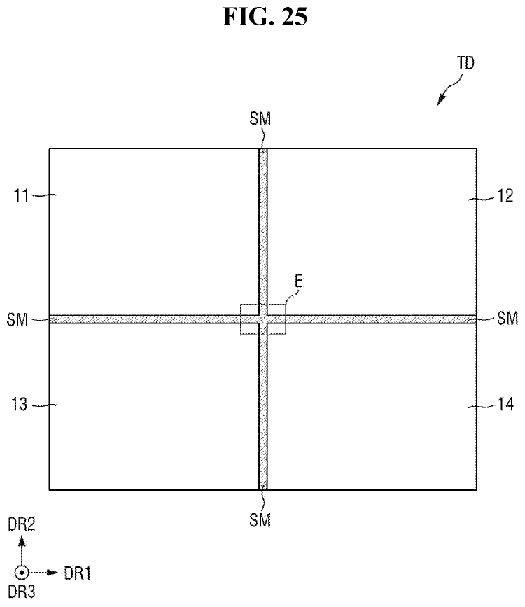

FIG. 25 is a perspective view illustrating a tiled display device including a plurality of display devices according to one or more embodiments.

Referring to FIG. 25, a tiled display device TD may include a plurality of display devices 11, 12, 13, and 14, and a seam SM. For example, the tiled display device TD may include the first display device 11, the second display device 12, the third display device 13, and the fourth display device 14.

The plurality of display devices 11, 12, 13, and 14 may be arranged in a grid shape. The plurality of display devices 11, 12, 13, and 14 may be arranged in a matrix shape in M (M being a positive integer) rows and N (N being a positive integer) columns. For example, the first display device 11 and the second display device 12 may be adjacent to each other in the first direction DR1. The first display device 11 and the third display device 13 may be adjacent to each other in the second direction DR2. The third display device 13 and the fourth display device 14 may be adjacent to each other in the first direction DR1. The second display device 12 and the fourth display device 14 may be adjacent to each other in the second direction DR2.

However, the number and arrangement of the plurality of display devices 11, 12, 13, and 14 in the tiled display device TD are not limited to those illustrated in FIG. 25. The number and arrangement of the display devices 11, 12, 13, and 14 in the tiled display device TD may be determined by the sizes of the display device 10 and the tiled display device TD and the shape of the tiled display device TD.

The plurality of display devices 11, 12, 13, and 14 may have the same size, but the present disclosure is not limited thereto. For example, the plurality of display devices 11, 12, 13, and 14 may have different sizes.

Each of the plurality of display devices 11, 12, 13, and 14 may have a rectangular shape including long sides and short sides. The plurality of display devices 11, 12, 13, and 14 may be disposed such that the long sides or the short sides thereof are connected to each other. Some or all of the plurality of display devices 11, 12, 13, and 14 may be disposed at the edge of the tiled display device TD, and may form one side of the tiled display device TD. At least one of the plurality of display devices 11, 12, 13, and 14 may be disposed at at least one corner of the tiled display device TD, and may form two adjacent sides of the tiled display device TD. At least one of the plurality of display devices 11, 12, 13, and 14 may be surrounded by other display devices.

Each of the plurality of display devices 11, 12, 13, and 14 may be substantially the same as the display device 10 described in conjunction with FIG. 1. Therefore, a description of each of the plurality of display devices 11, 12, 13, and 14 will be omitted.

The seam SM may include a coupling member or an adhesive member. In this case, the plurality of display devices 11, 12, 13, and 14 may be connected to each other by the coupling member or the adhesive member of the seam SM. The seam SM may be disposed between the first display device 11 and the second display device 12, between the first display device 11 and the third display device 13, between the second display device 12 and the fourth display device 14, and between the third display device 13 and the fourth display device 14.

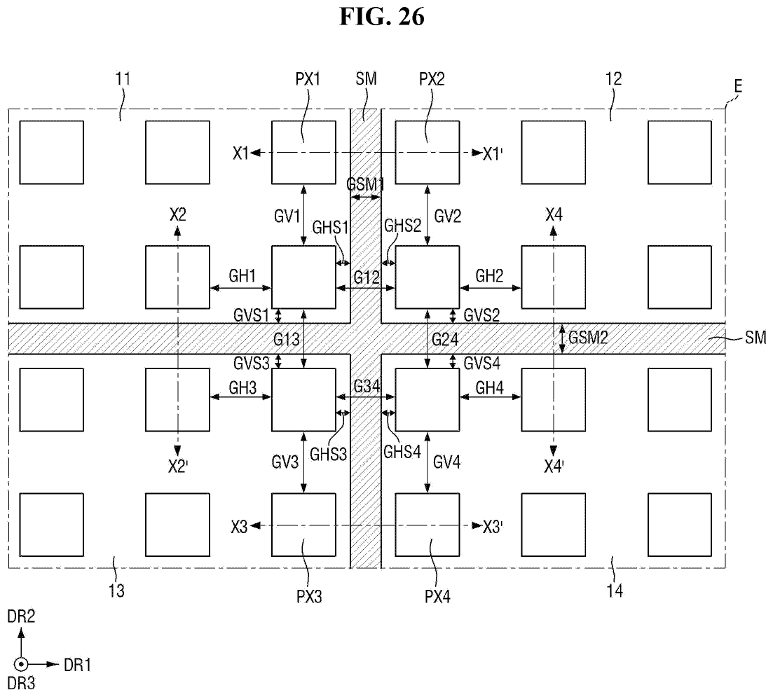

FIG. 26 is an enlarged view of an area E of FIG. 25.

Referring to FIG. 26, the seam SM may have a planar shape of the Chinese character ‘ten’, a cross, or a plus sign at the central region of the tiled display device TD where the first display device 11, the second display device 12, the third display device 13, and the fourth display device 14 are adjacent to each other. The seam SM may be disposed between the first display device 11 and the second display device 12, between the first display device 11 and the third display device 13, between the second display device 12 and the fourth display device 14, and between the third display device 13 and the fourth display device 14.

The first display device 11 may include first pixels PX1 arranged in a matrix form along the first direction DR1 and the second direction DR2 to display an image. The second display device 12 may include second pixels PX2 arranged in a matrix form along the first direction DR1 and the second direction DR2 to display an image. The third display device 13 may include third pixels PX3 arranged in a matrix form along the first direction DR1 and the second direction DR2 to display an image. The fourth display device 14 may include fourth pixels PX4 arranged in a matrix form along the first direction DR1 and the second direction DR2 to display an image.

A minimum distance between the first pixels PX1 adjacent in the first direction DR1 may be defined as a first horizontal separation distance GH1, and a minimum distance between the second pixels PX2 adjacent in the first direction DR1 may be defined as a second horizontal separation distance GH2. The first horizontal separation distance GH1 and the second horizontal separation distance GH2 may be substantially the same.

The seam SM may be disposed between the first pixel PX1 and the second pixel PX2 adjacent in the first direction DR1. A minimum distance G12 between the first pixel PX1 and the second pixel PX2 adjacent in the first direction DR1 may be the sum of a minimum distance GHS1 between the first pixel PX1 and the seam SM in the first direction DR1, a minimum distance GHS2 between the second pixel PX2 and the seam SM in the first direction DR1, and a width GSM1 of the seam SM in the first direction DR1.

The minimum distance G12 between the first pixel PX1 and the second pixel PX2 adjacent in the first direction DR1, the first horizontal separation distance GH1, and the second horizontal separation distance GH2 may be substantially the same. To this end, the minimum distance GHS1 between the first pixel PX1 and the seam SM in the first direction DR1 may be smaller than the first horizontal separation distance GH1, and the minimum distance GHS2 between the second pixel PX2 and the seam SM in the first direction DR1 may be smaller than the second horizontal separation distance GH2. In addition, the width GSM1 of the seam SM in the first direction DR1 may be smaller than the first horizontal separation distance GH1 or the second horizontal separation distance GH2.

A minimum distance between the third pixels PX3 adjacent in the first direction DR1 may be defined as a third horizontal separation distance GH3, and a minimum distance between the fourth pixels PX4 adjacent in the first direction DR1 may be defined as a fourth horizontal separation distance GH4. The third horizontal separation distance GH3 and the fourth horizontal separation distance GH4 may be substantially the same.

The seam SM may be disposed between the third pixel PX3 and the fourth pixel PX4 adjacent in the first direction DR1. A minimum distance G34 between the third pixel PX3 and the fourth pixel PX4 adjacent in the first direction DR1 may be the sum of a minimum distance GHS3 between the third pixel PX3 and the seam SM in the first direction DR1, a minimum distance GHS4 between the fourth pixel PX4 and the seam SM in the first direction DR1, and the width GSM1 of the seam SM in the first direction DR1.

The minimum distance G34 between the third pixel PX3 and the fourth pixel PX4 adjacent in the first direction DR1, the third horizontal separation distance GH3, and the fourth horizontal separation distance GH4 may be substantially the same. To this end, the minimum distance GHS3 between the third pixel PX3 and the seam SM in the first direction DR1 may be smaller than the third horizontal separation distance GH3, and the minimum distance GHS4 between the fourth pixel PX4 and the seam SM in the first direction DR1 may be smaller than the fourth horizontal separation distance GH4. In addition, the width GSM1 of the seam SM in the first direction DR1 may be smaller than the third horizontal separation distance GH3 or the fourth horizontal separation distance GH4.

A minimum distance between the first pixels PX1 adjacent in the second direction DR2 may be defined as a first vertical separation distance GV1, and a minimum distance between the third pixels PX3 adjacent in the second direction DR2 may be defined as a third vertical separation distance GV3. The first vertical separation distance GV1 and the third vertical separation distance GV3 may be substantially the same.

The seam SM may be disposed between the first pixel PX1 and the third pixel PX3 adjacent in the second direction DR2. A minimum distance G13 between the first pixel PX1 and the third pixel PX3 adjacent in the second direction DR2 may be the sum of a minimum distance GVS1 between the first pixel PX1 and the seam SM in the second direction DR2, a minimum distance GVS3 between the third pixel PX3 and the seam SM in the second direction DR2, and a width GSM2 of the seam SM in the second direction DR2.

The minimum distance G13 between the first pixel PX1 and the third pixel PX3 adjacent in the second direction DR2, the first vertical separation distance GV1, and the third vertical separation distance GV3 may be substantially the same. To this end, the minimum distance GVS1 between the first pixel PX1 and the seam SM in the second direction DR2 may be smaller than the first vertical separation distance GV1, and the minimum distance GVS3 between the third pixel PX3 and the seam SM in the second direction DR2 may be smaller than the third vertical separation distance GV3. In addition, the width GSM2 of the seam SM in the second direction DR2 may be smaller than the first vertical separation distance GV1 or the third vertical separation distance GV3.

A minimum distance between the second pixels PX2 adjacent in the second direction DR2 may be defined as a second vertical separation distance GV2, and a minimum distance between the fourth pixels PX4 adjacent in the second direction DR2 may be defined as a fourth vertical separation distance GV4. The second vertical separation distance GV2 and the fourth vertical separation distance GV4 may be substantially the same.

The seam SM may be disposed between the second pixel PX2 and the fourth pixel PX4 adjacent in the second direction DR2. A minimum distance G24 between the second pixel PX2 and the fourth pixel PX4 adjacent in the second direction DR2 may be the sum of a minimum distance GVS2 between the second pixel PX2 and the seam SM in the second direction DR2, a minimum distance GVS4 between the fourth pixel PX4 and the seam SM in the second direction DR2, and the width GSM2 of the seam SM in the second direction DR2.

The minimum distance G24 between the second pixel PX2 and the fourth pixel PX4 adjacent in the second direction DR2, the second vertical separation distance GV2, and the fourth vertical separation distance GV4 may be substantially the same. To this end, the minimum distance GVS2 between the second pixel PX2 and the seam SM in the second direction DR2 may be smaller than the second vertical separation distance GV2, and the minimum distance GVS4 between the fourth pixel PX4 and the seam SM in the second direction DR2 may be smaller than the fourth vertical separation distance GV4. In addition, the width GSM2 of the seam SM in the second direction DR2 may be smaller than the second vertical separation distance GV2 or the fourth vertical separation distance GV4.

As shown in FIG. 26, the minimum distance between pixels of adjacent display devices may be substantially the same as the minimum distance between pixels of each of the display devices in order to prevent the seam SM from being visually recognized between the images displayed by the plurality of display devices 11, 12, 13, and 14.

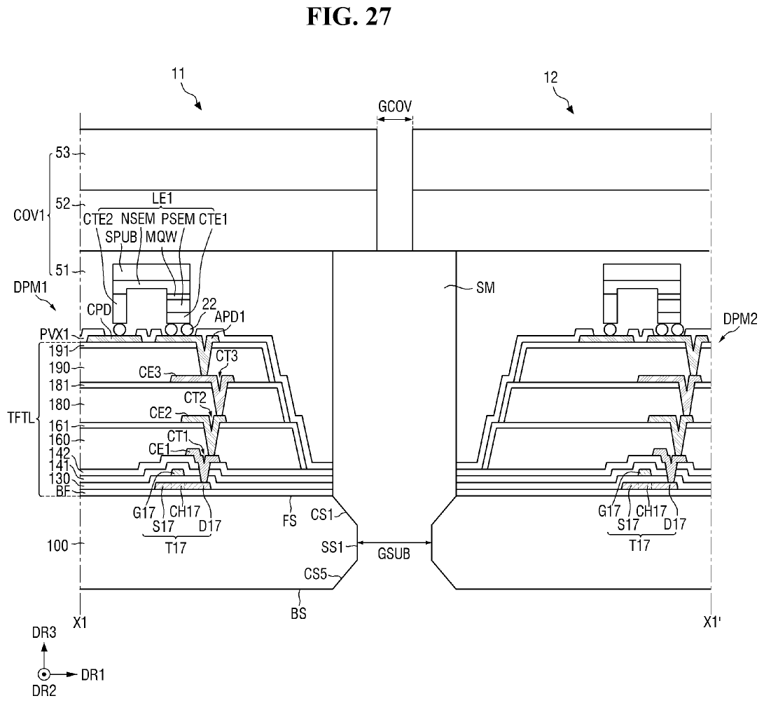

FIG. 27 is a cross-sectional view illustrating an example of a tiled display device taken along the line X1-X1′ of FIG. 26.

Referring to FIG. 27, the first display device 11 includes a first display module DPM1 and a first front cover COV1. The second display device 12 includes a second display module DPM2 and a second front cover COV2.

Each of the first display module DPM1 and the second display module DPM2 includes the substrate 100, the thin film transistor layer TFTL, and a light emitting element layer. The thin film transistor layer TFTL and the light emitting element layer have already been described in detail with reference to FIGS. 10 and 11. In FIG. 27, the redundant description of the previous embodiment will be omitted.

The first front cover COV1 may be disposed on the first chamfered surface CS1 of the substrate 100. That is, the first front cover COV1 may protrude more than the substrate 100 in the first direction DR1 and the second direction DR2. Therefore, a gap GSUB between the substrate 100 of the first display device 11 and the substrate 100 of the second display device 12 may be greater than a gap GCOV between the first front cover COV1 and the second front cover COV2.

Each of the first front cover COV1 and the second front cover COV2 may include an adhesive member 51, a light transmittance control layer 52 disposed on the adhesive member 51, and an anti-glare layer 53 disposed on the light transmittance control layer 52.

The adhesive member 51 of the first front cover COV1 serves to attach the light emitting element layer EML of the first display module DPM1 to the first front cover COV1. The adhesive member 51 of the second front cover COV2 serves to attach a light emitting element layer of the second display module DPM2 to the second front cover COV2. The adhesive member 51 may be a transparent adhesive member capable of transmitting light. For example, the adhesive member 51 may be an optically clear adhesive film or an optically clear resin.

The anti-glare layer 53 may be designed to diffusely reflect external light in order to prevent the visibility of an image from being deteriorated due to the external light being reflected as it is. Accordingly, the contrast ratio of an image displayed on the first display device 11 and the second display device 12 may increase due to the anti-glare layer 53.

The light transmittance control layer 52 may be designed to reduce the transmittance of the external light or light reflected from the first display module DPM1 and the second display module DPM2. Accordingly, the gap GSUB between the substrate 100 of the first display module DPM1 and the substrate 100 of the second display module DPM2 may be prevented from being visually recognized from the outside.

The anti-glare layer 53 may be implemented as a polarizing plate, and the light transmittance control layer 52 may be implemented as a phase delay layer, but the present disclosure is not limited thereto.

An example of a tiled display device taken along the lines X2-X2′, X3-X3′, and X4-X4′ of FIG. 26 is substantially the same as an example of a tiled display device taken along line X1-X1′ described in conjunction with FIG. 27, so that description thereof will be omitted.

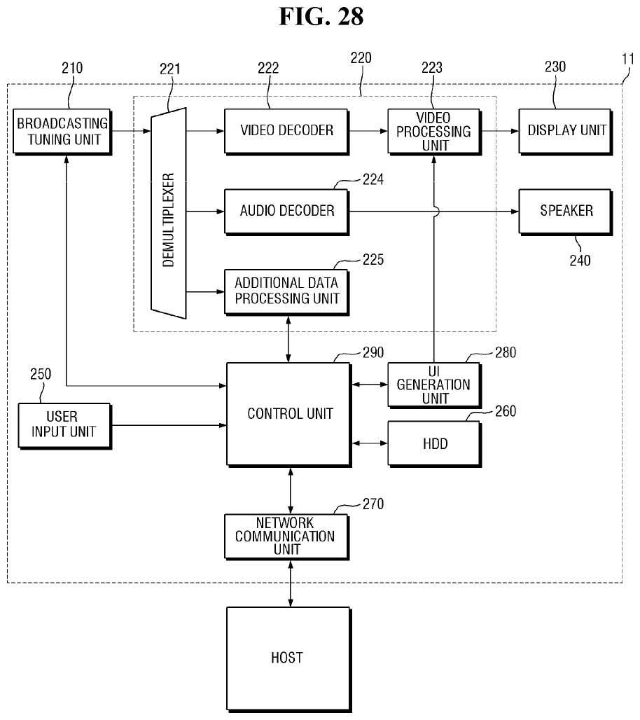

FIG. 28 is a block diagram illustrating a tiled display device according to one or more embodiments.

FIG. 28 illustrates the first display device 11 and a host system HOST for simplicity of description.

Referring to FIG. 28, the tiled display device TD according to one or more embodiments may include the host system HOST, a broadcast tuning unit 210, a signal processor 220, a display unit 230, a speaker 240, a user input unit 250, a hard disk drive (HDD) 260, a network communication unit 270, a UI generator 280, and a controller 290.

The host system HOST may be implemented as any one of a television system, a home theater system, a set-top box, a navigation system, a DVD player, a Blu-ray player, a personal computer (PC), a mobile phone system, and a tablet.

A user's command may be inputted to the host system HOST in various formats. For example, a command by a user's touch input may be inputted to the host system HOST. Alternatively, a user's command by a keyboard input or a button input of a remote controller may be inputted to the host system HOST.

The host system HOST may receive original video data corresponding to an original image from the outside. The host system HOST may divide the original video data by the number of the display devices. For example, in response to the first display device 11, the second display device 12, the third display device 13, and the fourth display device 14 (e.g., see FIG. 25), the host system HOST may divide the original video data into a first video data corresponding to a first image, a second video data corresponding to a second image, a third video data corresponding to a third image, and a fourth video data corresponding to a fourth image. The host system HOST may transmit the first video data to the first display device 11, the second video data to the second display device 12, the third video data to the third display device 13, and the fourth video data to the fourth display device 14 (e.g., see FIG. 25).

The first display device 11 may display the first image according to the first video data, the second display device 12 may display the second image according to the second video data, the third display device 13 may display the third image according to the third video data, and the fourth display device 14 may display the fourth image according to the fourth video data. Accordingly, the user may view the original image in which the first to fourth images displayed on the first to fourth display devices 11, 12, 13 and 14 are combined.

The first display device 11 may include the broadcast tuning unit 210, the signal processor 220, the display unit 230, the speaker 240, the user input unit 250, the HDD 260, the network communication unit 270, the UI generator 280, and the controller 290.

The broadcast tuning unit 210 may tune a desired channel frequency (e.g., a predetermined channel frequency) under the control of the controller 290 to receive a broadcast signal of the corresponding channel through an antenna. The broadcast tuning unit 210 may include a channel detection module and an RF demodulation module.

The broadcast signal demodulated by the broadcast tuning unit 210 is processed by the signal processor 220 and outputted to the display unit 230 and the speaker 240. Here, the signal processor 220 may include a demultiplexer 221, a video decoder 222, a video processor 223, an audio decoder 224, and an additional data processor 225.

The demultiplexer 221 separates the demodulated broadcast signal into a video signal, an audio signal, and additional data. The separated video signal, audio signal, and additional data are restored by the video decoder 222, the audio decoder 224, and the additional data processor 225, respectively. In this case, the video decoder 222, the audio decoder 224, and the additional data processor 225 restore them in a decoding format corresponding to an encoding format at the time of transmitting a broadcast signal.

In one or more embodiments, the decoded video signal is converted by the video processor 223 to have a vertical frequency, a resolution, an aspect ratio, and the like suitable for the output standard of the display unit 230, and the decoded audio signal is outputted to the speaker 240.

The display unit 230, which is a device for displaying an image, includes the above-described pixel PX, a panel driver, and the like.

The user input unit 250 may receive the signal transmitted by the host system HOST. The user input unit 250 may be provided to allow a user to select a command related to communication with other display devices as well as data related to selection of a channel transmitted by the host system HOST and selection and manipulation of a user interface (UI) menu, and to input the input data.

The storage device HDD 260, which stores various software programs including OS programs, recorded broadcast programs, moving pictures, photos, and other data, may include a storage medium such as a hard disk, a non-volatile memory, or the like.

The network communication unit 270, which is used for short-distance communication with the host system HOST and other display devices, may be implemented as a communication module including an antenna pattern capable of implementing mobile communication, data communication, Bluetooth, RF, Ethernet, or the like.

The network communication unit 270 may transmit/receive a wireless signal with at least one of a base station, an external terminal, or a server on a mobile communication network constructed based on technical standards or communication methods (e.g., global system for mobile communication (GSM), code division multi access (CDMA), code division multi access (CDMA2000), enhanced voice-data optimized or enhanced voice-data only (EV-DO), wideband CDMA (WCDMA), high speed downlink packet access (HSDPA), high speed uplink packet access (HSUPA), long term evolution (LTE), long term evolution-advanced (LTE-A), 5G, or the like) for mobile communication through an antenna pattern to be described later.

The network communication unit 270 may transmit/receive a wireless signal in a communication network according to wireless Internet technologies through an antenna pattern to be described later. Examples of the wireless internet techniques include wireless LAN (WLAN), wireless-fidelity (Wi-Fi), Wi-Fi direct, digital living network alliance (DLNA), wireless broadband (WiBro), world interoperability for microwave access (WiMAX), high speed downlink packet access (HSDPA), high speed uplink packet access (HSUPA), long term evolution (LTE), long term evolution-advanced (LTE-A), and the like. The antenna pattern transmits and receives data according to at least one of wireless internet techniques including even internet techniques not listed above.

The UI generator 280, which generates a UI menu for communication with the host system HOST and other display devices, may be implemented by an algorithm code and an OSD IC. The UI menu for communication with the host system HOST and other display devices may be a menu for designating a counterpart digital TV for communication and selecting a desired function.

The controller 290, which is responsible for overall control of the first display device 11 and communication control of the host system HOST and the second to fourth display devices 12, 13, and 14, may be implemented by a micro controller unit (MCU) in which the corresponding algorithm code for control is stored and the stored algorithm code is executed.

The controller 290 transmits the corresponding control command and data to the host system HOST and the second to fourth display devices 12, 13, and 14 through the network communication unit 270 in response to the input and selection of the user input unit 250. When receiving a suitable control command and data (e.g., a predetermined control command and data) from the host system HOST and the second to fourth display devices 12, 13, and 14, the controller 290 performs an operation according to the corresponding control command.

In one or more embodiments, the block diagram of the second display device 12, the block diagram of the third display device 13, and the block diagram of the fourth display device 14 are substantially the same as the block diagram of the first display device 11, so that description thereof will be omitted.

However, the aspects of embodiments of the present disclosure are not restricted to the one set forth herein. The above and other aspects of the present disclosure will become more apparent to one of daily skill in the art to which the present disclosure pertains by referencing the claims, with functional equivalents thereof to be included therein.

What is claimed is:

1. A display device comprising:
a substrate;
a plurality of electrode pads comprising a first electrode pad and a common electrode pad on the substrate;
a light emitting element comprising a first contact electrode on the first electrode pad and a second contact electrode on the common electrode pad;
a conductive adhesive member comprising a plurality of conductive balls connecting the first electrode pad and the first contact electrode and connecting the common electrode pad and the second contact electrode; and
a plurality of protrusions on the substrate and protruding in a thickness direction of the substrate,
wherein first protrusions from among the plurality of protrusions overlap the plurality of electrode pads in the thickness direction of the substrate.

2. The display device of claim 1, wherein second protrusions from among the plurality of protrusions are located between the first electrode pad and the common electrode pad.

3. The display device of claim 1, wherein at least some of the plurality of conductive balls are located between the plurality of protrusions.

4. The display device of claim 1, wherein the first protrusions protrude from top surfaces of the plurality of electrode pads.

5. The display device of claim 2, further comprising:
a planarization layer between the plurality of electrode pads and the substrate; and
a pixel defining layer on the planarization layer and surrounding the plurality of electrode pads,
wherein the second protrusions are on a same plane as the pixel defining layer and the plurality of electrode pads.

6. The display device of claim 5, wherein the first protrusions and the second protrusions comprise a same material as the pixel defining layer.

7. The display device of claim 5, further comprising a first passivation layer on the pixel defining layer,
wherein the first protrusions are not covered by the first passivation layer, and the second protrusions are covered by the first passivation layer.

8. The display device of claim 1, wherein the first protrusions are under the plurality of electrode pads.

9. The display device of claim 2, further comprising a planarization layer between the plurality of electrode pads and the substrate,
wherein the first protrusions protrude from one surface of the planarization layer.

10. The display device of claim 1, further comprising:
a planarization layer between the plurality of electrode pads and the substrate;
a pixel defining layer on the planarization layer and surrounding the plurality of electrode pads; and
a first passivation layer on some of the plurality of electrode pads and the pixel defining layer,
wherein the plurality of protrusions comprises a same material as the first passivation layer.

11. The display device of claim 10, wherein the plurality of protrusions further comprises a second protrusion between the first electrode pad and the common electrode pad in a plan view, and
wherein the first protrusions are on one surface of the electrode pad, and the second protrusions protrude from one surface of the first passivation layer.

12. The display device of claim 1, wherein a maximum length of a protrusion from among the plurality of protrusions is smaller than a diameter of a conductive ball from among the plurality of conductive balls.

13. The display device of claim 12, wherein the maximum length of the protrusion is about 0.5 μm to 1.5 μm, and the diameter of the conductive ball is about 3 to 5 μm.

14. The display device of claim 1, wherein the plurality of protrusions have a shape such as a hemisphere, a triangular pyramid, a quadrangular pyramid, and a donut.

15. The display device of claim 1, wherein a thickness of the first contact electrode is smaller than a thickness of the second contact electrode.

16. The display device of claim 1, wherein the first electrode pad and the common electrode pad are adjacent to each other in a first direction and extend in a second direction crossing the first direction, and
wherein the light emitting element is a flip chip type micro light emitting diode located between the first electrode pad and the common electrode pad.

17. A display device comprising:
a substrate;
a plurality of electrode pads comprising a first electrode pad and a common electrode pad on the substrate;
a light emitting element comprising a first contact electrode on the first electrode pad and a second contact electrode on the common electrode pad; and
a conductive adhesive member comprising a plurality of conductive balls connecting the first electrode pad and the first contact electrode and connecting the common electrode pad and the second contact electrode,
wherein the first electrode pad has a first recess recessed from a top surface of the first electrode pad, and the common electrode pad has a second recess recessed from a top surface of the common electrode pad.

18. The display device of claim 17, wherein the plurality of conductive balls is in the first recess and the second recess, and
wherein a diameter of each of the plurality of conductive balls is greater than a recessed thickness of each of the first recess and the second recess.

19. The display device of claim 17, wherein the recessed thickness of the first recess is at least ⅓ of a thickness of the first electrode pad.

20. The display device of claim 17, wherein the first electrode pad has a first protrusion protruding from a top surface of the first recess, and
wherein the common electrode pad has a second protrusion protruding from a top surface of the second recess.

21. The display device of claim 20, wherein in the first electrode pad, the first recess and the first protrusion are arranged to be spaced along one direction, and
wherein in the common electrode pad, the second recess and the second protrusion are arranged to be spaced along the one direction.

22. The display device of claim 17, wherein the light emitting element overlaps the first recess and the second recess in a thickness direction of the substrate, and is a flip chip type micro light emitting diode.

23. A display device comprising:
a substrate;
a plurality of electrode pads comprising a first electrode pad and a common electrode pad on the substrate;
a light emitting element comprising a first contact electrode on the first electrode pad and a second contact electrode on the common electrode pad;
a conductive adhesive member comprising a plurality of conductive balls connecting the first electrode pad and the first contact electrode and connecting the common electrode pad and the second contact electrode; and
a dielectric layer on the substrate between the first electrode pad and the common electrode pad in a plan view, the dielectric layer having a reverse taper shape having a lateral inclination in which a length decreases from a top surface to a bottom surface.

24. A tiled display device comprising a plurality of display devices and a seam located between the plurality of display devices, wherein a first display device from among the plurality of display devices comprises:
a substrate;
a plurality of electrode pads comprising a first electrode pad and a common electrode pad on a first surface of the substrate;
a light emitting element comprising a first contact electrode on the first electrode pad and a second contact electrode on the common electrode pad;
a conductive adhesive member comprising a plurality of conductive balls connecting the first electrode pad and the first contact electrode and connecting the common electrode pad and the second contact electrode; and
a plurality of protrusions on the substrate and protruding in a thickness direction of the substrate,
wherein first protrusions from among the plurality of protrusions overlap the plurality of electrode pads in the thickness direction of the substrate.

25. The tiled display device of claim 24, wherein the light emitting element is a flip chip type micro light emitting diode.

26. The tiled display device of claim 24, wherein the substrate comprises glass.

27. The tiled display device of claim 24, wherein the first display device further comprises:
a pad on the first surface of the substrate; and
a side line on the first surface of the substrate, a second surface opposite to the first surface, and one side surface between the first surface and the second surface, and connected to the pad.

28. The tiled display device of claim 27, wherein the first display device further comprises:
a connection line on the second surface of the substrate; and
a flexible film connected to the connection line through the conductive adhesive member,
wherein the side line is connected to the connection line.

29. The tiled display device of claim 24, wherein the plurality of display devices are arranged in a matrix form in M rows and N columns.
